(19) United States
(12) Patent Application Publication
(10) Pub. No.: US 2025/0194229 A1
(43) Pub. Date: Jun. 12, 2025

(54) SEMICONDUCTOR DEVICE AND METHOD OF MANUFACTURING THE SAME

(71) Applicant: Renesas Electronics Corporation, Tokyo (JP)

(72) Inventors: Hideaki TSUCHIYA, Tokyo (JP); Shunichi NAKAMURA, Tokyo (JP); Naoki TAKIZAWA, Tokyo (JP)

(21) Appl. No.: 18/926,489

(22) Filed: Oct. 25, 2024

(30) Foreign Application Priority Data
Dec. 11, 2023 (JP) 2023-208126

(51) Int. Cl. H01L 27/06; H01L 29/66; H01L 29/739

(52) U.S. Cl. CPC H10D 84/615; H10D 1/47; H10D 12/038; H10D 12/481

(57) ABSTRACT

Reliability of a semiconductor device is improved. A resistance element and a trench form a closed path in plan view.

The semiconductor device includes: first and second contact members each electrically connecting a gate pad and the resistance element; third and fourth contact members each electrically connecting a gate wiring and the resistance element; and fifth to eighth contact members each electrically connecting a first conductive member and the resistance element. A current path passing from the gate pad to the gate wiring through the first conductive member is made of the plurality of contact members and the resistance element. The first conductive member functions together with the fifth to eighth contact members to form a bypass path for reducing the current that flows through some sections of the closed path made of the resistance element.

### CROSS-REFERENCE TO RELATED APPLICATION

The disclosure of Japanese Patent Application No. 2023-208126 filed on Dec. 11, 2023, including the specification, drawings and abstract is incorporated herein by reference in its entirety.

### BACKGROUND

The present invention relates to a semiconductor device and a method of manufacturing the same, and particularly to a semiconductor device including a resistance element used to connect a gate pad and a gate wiring electrically, and a method of manufacturing the semiconductor device.

In an IGBT (Insulated Gate Bipolar Transistor) or the like, in some cases, a resistance element is interposed between a gate wiring connected to a gate electrode and a gate pad to adjust or limit the switching speed of the IGBT or the like, or to prevent oscillation that occurs when a plurality of IGBTs are connected in parallel.

There is disclosed technique listed below.

[Patent Document 1] Japanese Unexamined Patent Application Publication No. 2022-82244

The Patent Document 1 describes an IGBT equipped with a built-in resistance element connected in series between a gate pad and a trench gate electrode. The built-in resistance element is formed directly above a P-type semiconductor region through an insulating film and is electrically connected to a gate electrode.

For layouts for a resistance element, various types of those can be adopted. For example, by adopting a layout where a resistance element with an (endless) trench structure having a loop shape in plan view is interposed between a gate pad and a gate wiring, the switching speed can be adjusted or limited, or the oscillation that occurs when a plurality of IGBTs are connected in parallel can be prevented. In one example, a resistance element is formed by forming a trench and then embedding polysilicon in the trench. The trench may be formed so that the width of the trench in plan view is made narrow at a border that is a folded portion of the loop shape, mainly from the viewpoint of embedding property of polysilicon.

In this case, a portion with the particularly narrow trench width has a relatively large risk of short circuit of the resistance element due to electromigration caused by continuous flow of current. In other words, a portion with the narrow trench width is low in electromigration resistance. Accordingly, when a resistance element including a trench structure with a narrow width is adopted, the influence of the electromigration needs to be suppressed by reducing the current that flows in the portion with the narrow width, from the viewpoint of the requirements for downsizing of the device structure or the embedding property of polysilicon in the trench.

Other issues and novel characteristics will be apparent from the description of the specification and the accompanying drawings.

The outline of the typical aspects of the embodiments disclosed in the present application will be briefly described as follows. In a semiconductor device according to one embodiment, a resistance element electrically connecting a gate pad and a gate wiring and a trench housing the resistance element form a closed path in plan view. The semiconductor device includes: first and second contact members each electrically connecting the gate pad and the resistance element; third and fourth contact members each electrically connecting the gate wiring and the resistance element; and fifth to eighth contact members each electrically connecting a first conductive member and the resistance element. A current path passing from the gate pad to the gate wiring through the first conductive member is made of the plurality of contact members and the resistance element. The first conductive member functions together with the fifth to eighth contact members to form a bypass path for reducing the current that flows through some sections of the closed path made of the resistance element.

A method of manufacturing a semiconductor device according to one embodiment includes: a step of forming a well region on a first main surface of a semiconductor substrate; a step of forming a trench in a well region, the trench forming a closed path in plan view; a step of forming an insulating film inside the trench; a step of forming a resistance element inside the trench through the insulating film; a step of forming an interlayer insulating film on the first main surface; a step of forming first to eighth contact members penetrating the interlayer insulating film and reaching the resistance element; and a step of forming a gate pad, a gate wiring, and a first conductive member on the interlayer insulating film. The first and second contact members each electrically connects the gate pad and the resistance element, the third and fourth contact members each electrically connects the gate wiring and the resistance element, and the fifth through eighth contact members each electrically connects the first conductive member and the resistance element. The first conductive member functions together with the fifth to eighth contact members to form a bypass path for reducing the current that flows in some sections of the closed path made of the resistance element.

According to one embodiment, reliability of a semiconductor device can be improved.

### BRIEF DESCRIPTIONS OF THE DRAWINGS

FIG. 1 is a plan view showing the entire semiconductor device in the first embodiment;

FIG. 2 is a conceptual equivalent circuit diagram showing the semiconductor device in the first embodiment;

FIG. 3 is a plan view of a principal part showing the semiconductor device in the first embodiment;

FIG. 4 is a plan view of a principal part showing the semiconductor device in the first embodiment;

FIG. 5 is a plan view of a principal part showing the semiconductor device in the first embodiment;

FIG. 6 is a cross-sectional view (A-A cross-sectional view) of the semiconductor device in the first embodiment;

FIG. 7 is a cross-sectional view (B-B cross-sectional view) of the semiconductor device in the first embodiment;

FIG. 8 is a cross-sectional view (C-C cross-sectional view) of the semiconductor device in the first embodiment;

FIG. 9 is a cross-sectional view (D-D cross-sectional view) of the semiconductor device in the first embodiment;

FIG. 10 is a plan view of a principal part showing a modification example of the semiconductor device in the first embodiment;

FIG. 11 is a plan view of a principal part showing the semiconductor device in the second embodiment;

FIG. 12 is a plan view of a principal part showing the semiconductor device in the second embodiment;

FIG. 13 is a plan view of a principal part showing a first modification example of the semiconductor device in the second embodiment;

FIG. 14 is a plan view of a principal part showing a second modification example of the semiconductor device in the second embodiment;

FIG. 15 is a plan view of a principal part showing a third modification example of the semiconductor device in the second embodiment;

FIG. 16 is a plan view of a principal part showing the semiconductor device in third embodiment 3;

FIG. 17 is a plan view of a principal part showing the semiconductor device in the third embodiment;

FIG. 18 is a plan view of a principal part showing a modification example of the semiconductor device in the third embodiment;

FIG. 19 is a plan view of a principal part showing the semiconductor device in the fourth embodiment;

FIG. 20 is a cross-sectional view (E-E cross-sectional view) showing the semiconductor device in the fourth embodiment;

FIG. 21 is a cross-sectional view (A-A cross-sectional view) showing a step of manufacturing the semiconductor device in the first embodiment;

FIG. 22 is a cross-sectional view (C-C cross-sectional view) showing a step of manufacturing of the semiconductor device in the first embodiment;

FIG. 23 is a cross-sectional view (A-A cross-sectional view) showing the manufacturing step continued from the manufacturing step shown in FIGS. 21 and 22;

FIG. 24 is a cross-sectional view (C-C cross-sectional view) showing the manufacturing step continued from the manufacturing step shown in FIGS. 21 and 22;

FIG. 25 is a cross-sectional view (A-A cross-sectional view) showing the manufacturing step continued from the manufacturing step shown in FIGS. 23 and 24;

FIG. 26 is a cross-sectional view (C-C cross-sectional view) showing the manufacturing step continued from the manufacturing step shown in FIGS. 23 and 24;

FIG. 27 is a cross-sectional view (A-A cross-sectional view) showing the manufacturing step continued from the manufacturing step shown in FIGS. 25 and 26;

FIG. 28 is a cross-sectional view (C-C cross-sectional view) showing the manufacturing step continued from the manufacturing step shown in FIGS. 25 and 26;

FIG. 29 is a cross-sectional view (A-A cross-sectional view) showing the manufacturing step continued from the manufacturing step shown in FIGS. 27 and 28;

FIG. 30 is a cross-sectional view (C-C cross-sectional view) showing the manufacturing step continued from the manufacturing step shown in FIGS. 27 and 28;

FIG. 31 is a cross-sectional view (A-A cross-sectional view) showing the manufacturing step continued from the manufacturing step shown in FIGS. 29 and 30;

FIG. 32 is a cross-sectional view (A-A cross-sectional view) showing the manufacturing step continued from the manufacturing step shown in FIG. 31;

FIG. 33 is a cross-sectional view (C-C cross-sectional view) showing the manufacturing step continued from the manufacturing step shown in FIG. 31;

FIG. 34 is a cross-sectional view (A-A cross-sectional view) showing the manufacturing step continued from the manufacturing step shown in FIGS. 32 and 33; and

FIG. 35 is a cross-sectional view (C-C cross-sectional view) showing the manufacturing step continued from the manufacturing step shown in FIGS. 32 and 33.

### SUMMARY

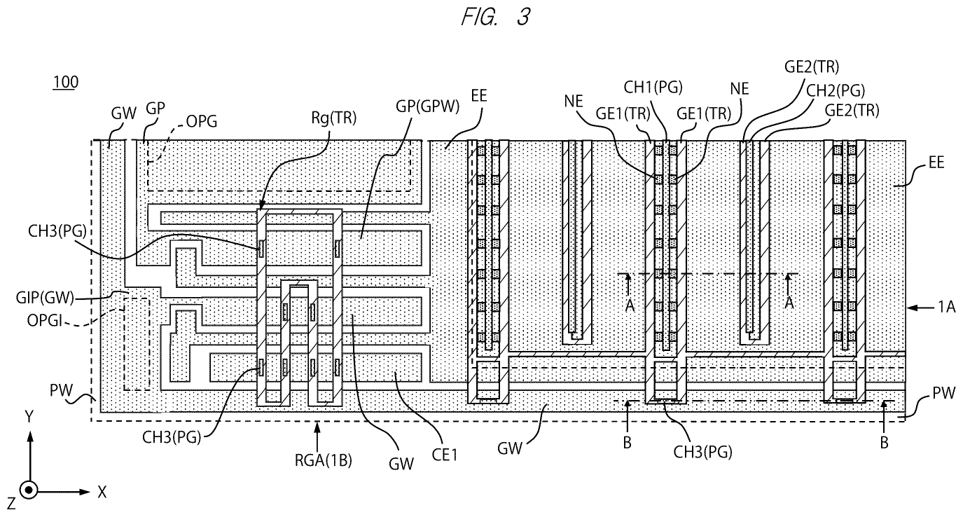

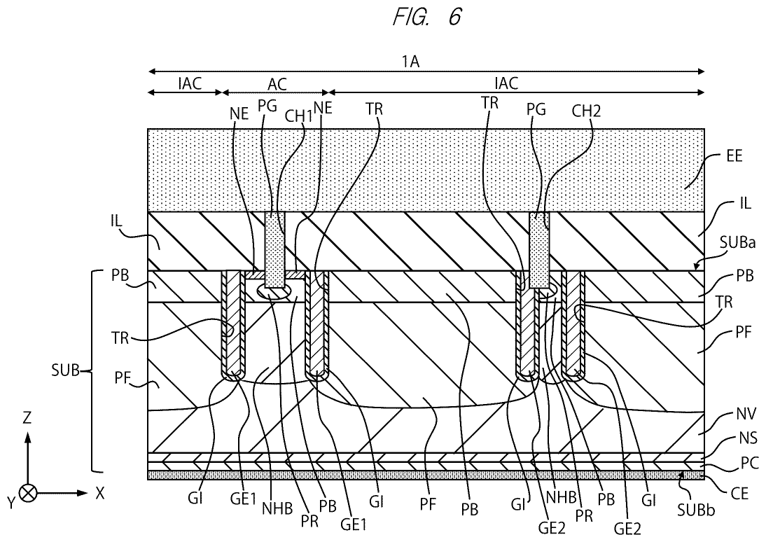

Hereinafter, embodiments will be described in detail with reference to the accompanying drawings. Note that components having the same function are denoted by the same reference symbols throughout all the drawings for describing the embodiments, and the repetitive description thereof will be omitted. Also, in the following embodiments, explanations of the same or similar parts are not repeated in principle, unless otherwise particularly required. In addition, FIGS. 3 to 5 and FIGS. 10 to 19 may not partially correctly illustrate the relationship of components in up and down directions in order to support the understanding of the shapes of the components. FIGS. 6 to 9 and FIGS. 20 to 35 which are cross-sectional views illustrate the relationship of components in up and down directions.

### First Embodiment

### Structure of Semiconductor Device

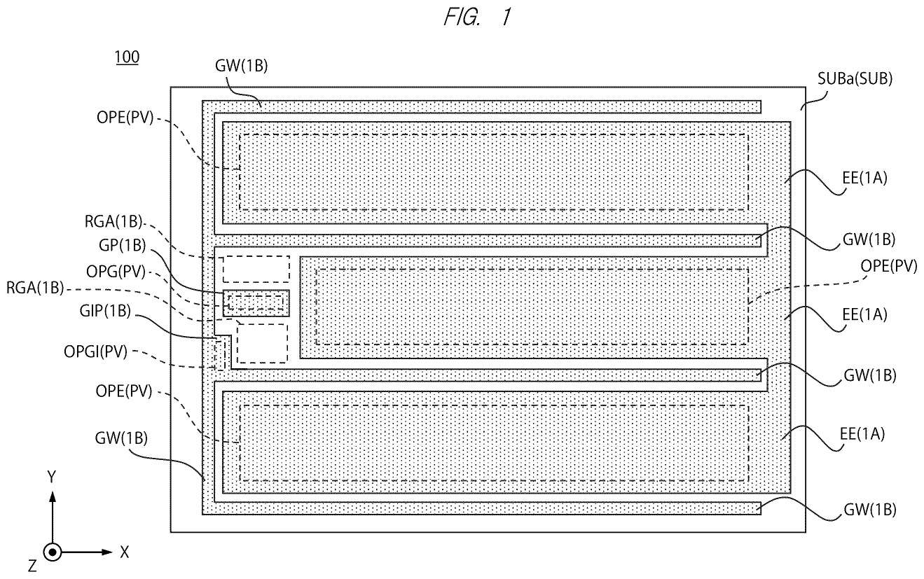

FIG. 1 is a plan view showing a semiconductor device 100 configured as a semiconductor chip. The semiconductor device 100 includes a cell region 1A including a cell configured as an IGBT and a peripheral region 1B being in the vicinity of the cell region 1A and including a gate wiring and the like. The cell region 1A includes a plurality of IGBT cells. In the example of FIG. 1, the cell region 1A is divided into three partial regions along the Y direction (at each of the boundaries between the partial regions, a gate wiring GW extends in the X direction orthogonal to the Y direction). The three partial regions are covered with an emitter electrode EE.

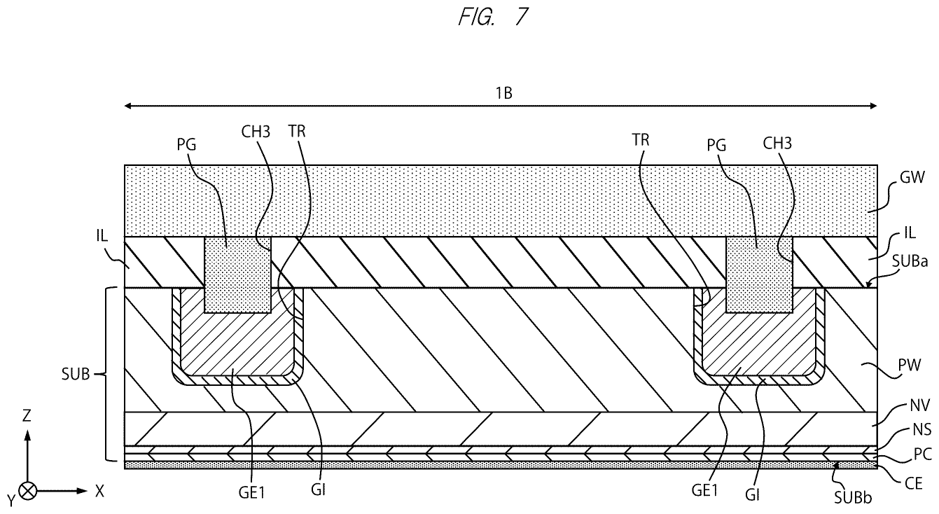

The peripheral region 1B includes a gate pad GP for applying voltage to a gate electrode GE1, the gate wiring GW for electrically connecting the gate pad GP and the gate electrode GE1, and a resistance element region RGA. Although the detailed shapes of the gate pad GP, the gate wiring GW, and the resistance element region RGA are omitted in FIG. 1, the gate pad GP and the gate wiring GW are electrically connected through a resistance element Rg formed in the resistance element region RGA as shown in FIG. 3 described later and the like, and the gate wiring GW is electrically connected to the gate electrode GE1 of the IGBT through a contact member (plug) PG formed in a contact hole CH3 described later (see the B-B cross-sectional view in FIG. 7).

Note that the emitter electrode EE, the gate pad GP, the gate wiring GW, and the resistance element region RGA are each covered with a protective film such as a polyimide film, and the protective film covering the emitter electrode EE and the protective film covering the gate pad GP have openings OPE and OPG, respectively. A terminal for external connection is connected to each of the portion of the emitter electrode EE exposed from the opening OPE and the portion of the gate pad GP exposed from the opening OPG, and the semiconductor device 100 is electrically connected to a lead frame, another semiconductor chip, a circuit board or the like through the terminals for external connection. The terminal for external connection is, for example, a bonding wire made of gold, copper, or aluminum, or a clip made of a copper plate.

Also, on the first main surface SUBa of the semiconductor substrate SUB, annular field plates are overlapped so as to surround the outer shape of the gate wiring GW. The innermost of the field plates is integrated with the end portion of the emitter electrode EE, the end being opposite to the gate pad GP side, and does not overlap and is separated from the gate wiring GW.

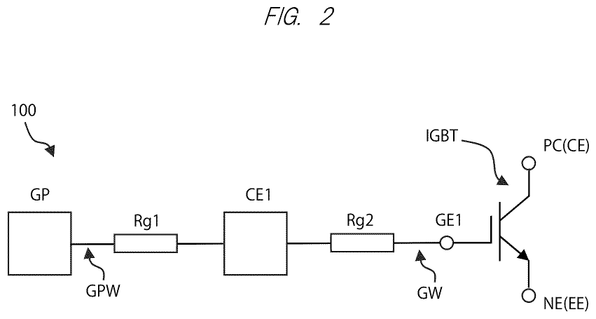

FIG. 2 is a conceptual equivalent circuit diagram of the semiconductor device 100. The IGBT includes a gate electrode GE1, a collector region PC, and an emitter region NE. The collector electrode CE is electrically connected to the collector region PC, and the emitter electrode EE is electrically connected to the emitter region NE. As described above, the gate pad GP and the gate electrode GEL are electrically connected through the resistance element. In more detail, as shown in FIG. 2, the gate pad GP is electrically connected to a first conductive member CE1 (such as a flat conductive pad, see FIG. 3 described later) through a resistance element part Rg1, and the first conductive member CE1 is electrically connected to the gate electrode GE1 through a resistance element part Rg2. In the example of FIG. 3, a portion of a first extended part P1 between the first contact member CM1 and the fifth contact member CM5 and a portion of a second extended part P2 between the second contact member CM2 and the eighth contact member CM8 correspond to the resistance element portion Rg1, and a portion of a third extended part P3 between the third contact member CM3 and the sixth contact member CM6 and a portion of a fourth extended part P4 between the fourth contact member CM4 and the seventh contact member CM7 correspond to the resistance element portion Rg2.

### Structure of IGBT

Each of FIGS. 3 to 5 is a plan view of a principal part of the region in the vicinity of the resistance element region RGA in the semiconductor device 100. FIG. 6 is a cross-sectional view taken along the line A-A in FIG. 3. FIG. 7 is a cross-sectional view taken along the line B-B in FIG. 3.

As shown in FIG. 6, the cell region 1A of the semiconductor device 100 has an active cell AC for performing the main operation of the IGBT and an inactive cell IAC other than the active cell AC. The IGBT shown in FIG. 6 is an IE-type IGBT, which enable the use of the IE (Injection Enhancement) effect that increases the concentration of charge stored in a drift region NV by making holes difficult to be discharged from the emitter electrode EE side when the IGBT is in an ON state. The gate electrode GE1 of the active cell AC is electrically connected to the gate wiring GW through the contact member PG filled in a contact hole CH3 (FIGS. 3 and 7), and the gate potential is supplied during IGBT operation. A gate electrode GE2 of the inactive cell IAC is electrically connected to the emitter electrode EE through the contact member PG filled in a contact hole CH2 (FIGS. 3 and 6), and the emitter potential is supplied during IGBT operation.

As shown in FIG. 3, in the cell region 1A, a trench TR (in the active cell AC) in which the gate electrode GE1 is formed and a trench TR (in the inactive cell IAC) in which the gate electrode GE2 is formed are formed alternately along the X direction while extending in the Y direction. The trench TR formed in the active cell AC and the gate electrode GEL formed inside the trench TR constitute a gate trench. The trench TR formed in the inactive cell IAC and the gate electrode GE2 formed inside the trench TR constitute an emitter trench. A contact hole CH1 is formed in the active cell AC, and the contact hole CH1 is filled with the contact member PG. A contact hole CH2 is formed in the inactive cell IAC, and the contact hole CH2 is filled with the contact member PG. Both the contact member PG in the contact hole CH1 and the contact member PG in the contact hole CH2 are electrically connected to the emitter electrode EE (FIG. 6). Also, the emitter region NE is formed in the active cell AC.

As shown in FIG. 6, the semiconductor device 100 includes an n-type semiconductor substrate SUB having a first main surface (upper surface) SUBa and a second main surface (lower surface) SUBb. The semiconductor substrate SUB is made of n-type silicon and has a low-concentration n-type semiconductor layer (drift region) NV. On the second main surface SUBb side of the semiconductor substrate SUB, an n-type field stop region (impurity region) NS having a higher impurity concentration than the drift region NV, a p-type collector region (impurity region) PC, and a collector electrode CE made of a metal film are formed. The field stop region NS is provided to suppress a depletion layer extending from a p-n junction on the upper surface side of the semiconductor substrate SUB from reaching the p-type collector region PC when the IGBT is turned off. During IGBT operation, collector potential is supplied to the collector region PC through the collector electrode CE. The collector electrode CE is either a single-layer metal film, such as an Au film, Ni film, Ti film, or AlSi film, or a stacked metal film where these films are stacked as appropriate.

On the first main surface SUBa side of the semiconductor substrate SUB, the trench TR is formed in the semiconductor substrate SUB. The trench TR penetrates the emitter region NE and/or a base region PB and reaches the inside of the semiconductor substrate SUB. The depth of the trench TR is, for example, 2 μm or more and 5 μm or less. A gate insulating film GI is formed inside the trench TR. The gate electrodes GE1 and GE2 are formed on the gate insulator GI so as to fill the inside of the trench TR. The gate insulating film GI is, for example, a silicon oxide film, and the gate electrodes GE1 and GE2 are, for example, polycrystalline silicon films (polysilicon films) doped with an n-type impurity. The thickness of the gate insulating film GI is, for example, 70 nm or more and 150 nm or less.

In the active cell AC, a hole barrier region (impurity region) NHB having a higher impurity concentration than the drift region NV is formed in the semiconductor substrate SUB between a pair of gate electrodes GE1. In the hole barrier region NHB, a p-type base region (impurity region) PB is formed. In the p-type base region PB, an n-type emitter region (impurity region) NE having a higher impurity concentration than the drift region NV is formed. The base region PB is formed so as to be shallower than the depth of the trench TR, and the emitter region NE is formed so as to be shallower than the depth of the base region PB. The base region PB located below the emitter region NE is used as the channel region.

In the inactive cell IAC, a hole barrier region NHB is formed in the semiconductor substrate SUB between a pair of gate electrodes GE2. Also, a p-type floating region (impurity region) PF is formed in the semiconductor substrate SUB between the gate electrodes GE1 and GE2. A p-type base region PB having a higher impurity concentration than the floating region PF is formed in the hole barrier region NHB and the floating region PF. The floating region PF is preferably formed down to a position deeper than the bottom of the trench TR to enhance the high breakdown voltage resistance, and more preferably is formed so as to cover the bottom of the trench TR. Also, in the inactive cell IAC, the floating region PF is formed in the semiconductor substrate SUB of the cell region 1A except for the portion between the pair of trenches TR. The floating region PF and the base region PB formed inside the floating region PF are not electrically connected to the gate wiring GW and the emitter electrode EE and are electrically floating.

On the first main surface SUBa of the semiconductor substrate SUB, an interlayer insulating film IL is formed so as to cover each trench TR. The interlayer insulating film IL is, for example, a silicon oxide film. The thickness of the interlayer insulating film IL is, for example, 600 nm or more and 1500 nm or less. Also, a planarizing process for planarizing the upper surface of the interlayer insulating film IL is performed to the interlayer insulating film IL. In the active cell AC, the contact hole CH1 penetrates the interlayer insulating film IL and the emitter region NE and reaches the base region PB. The contact hole CH1 is formed so as to be in contact with the emitter region NE and the base region PB. The contact member PG is embedded in the contact hole CH1, and the contact member PG is electrically connected to the emitter region NE and the base region PB. In the inactive cell IAC, the contact hole CH2 penetrates the interlayer insulating film IL and reaches the inside of the base region PB. The contact hole CH2 is formed so as to overlap the gate electrode GE2 in plan view. The contact member PG is embedded inside the contact hole CH2, and the contact member PG is electrically connected to the gate electrode GE2 and the base region PB. The contact member PG includes a barrier metal film and a conductive film formed on the barrier metal film. The barrier metal film is, for example, a stacked film of a titanium film and a titanium nitride film formed on the titanium film. The conductive film is, for example, a tungsten film.

A p-type high concentration diffusion region (impurity region) PR having a higher impurity concentration than the base region PB is formed around the bottom of the contact holes CH1 and CH2. The high concentration diffusion region PR is provided to decrease the contact resistance with the contact member PG and to prevent latch-up.

The emitter electrode EE is formed on the interlayer insulating film IL. The emitter electrode EE is electrically connected to the emitter region NE, the base region PB, and the high density diffusion region PR through the contact member PG, and supplies emitter potential to these regions. Although not shown in FIG. 6, the gate pad GP (including the gate pad wiring GPW) formed by the same process as the emitter electrode EE, the gate wiring GW, and the first conductive member CEL are also formed on the interlayer insulating film IL (FIGS. 3, and 7 to 9).

Such emitter electrode EE, gate pad GP, gate wiring GW, and first conductive member CE1 include a barrier metal film and a conductive film formed on the barrier metal film. The barrier metal film is, for example, a TiW film. The conductive film is, for example, an aluminum alloy film with copper or silicon added. The aluminum alloy film is a main conductive film of the emitter electrode EE and the gate wiring GW and is sufficiently thicker than the TiW film.

Also, as shown in FIG. 3, a pair of the gate electrodes GE1 are connected to each other and are electrically connected to the gate wiring GW in the peripheral region 1B through the contact member PG formed in the contact hole CH3. As shown in FIG. 7, a well region PW, which is a p-type semiconductor region, is provided in the peripheral region 1B. The gate electrode GE1 formed in the trench TR in the well region PW is electrically connected to the gate wiring GW through the contact member PG formed in the contact hole CH3. The well region PW is formed by the same process as that of the floating region PF in the cell region 1A, and therefore, has the same depth as that of the floating region PF. However, in plan view, the well region is physically separated from the floating region PF.

### Resistance Element and its Surrounding Structure

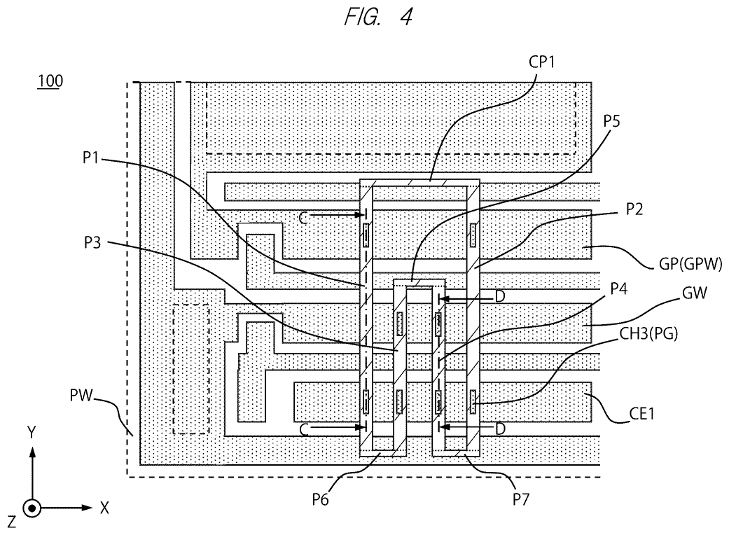

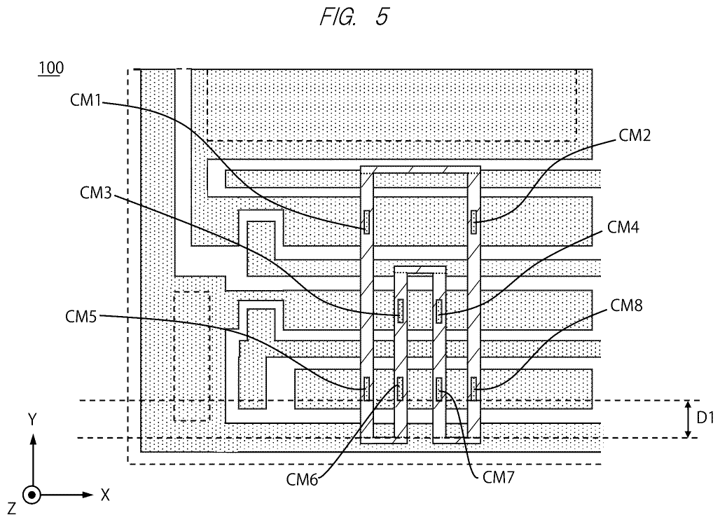

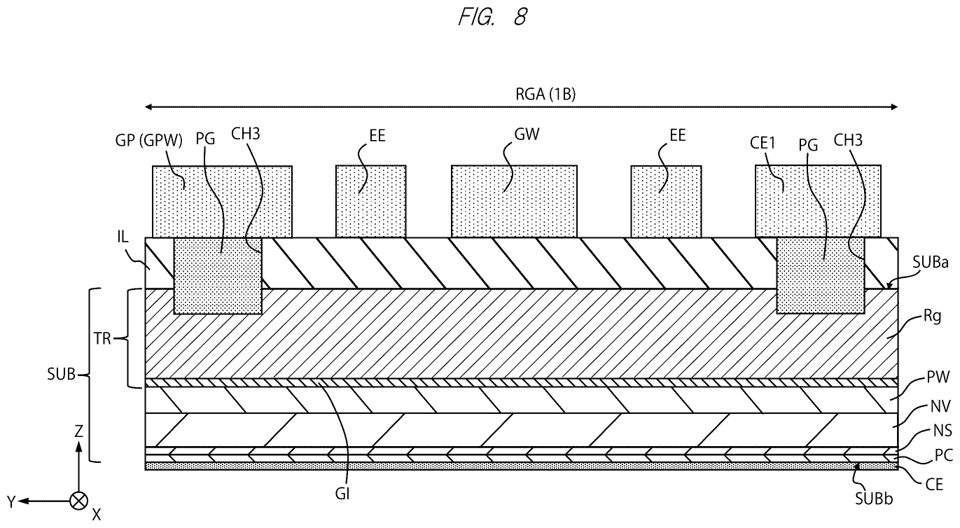

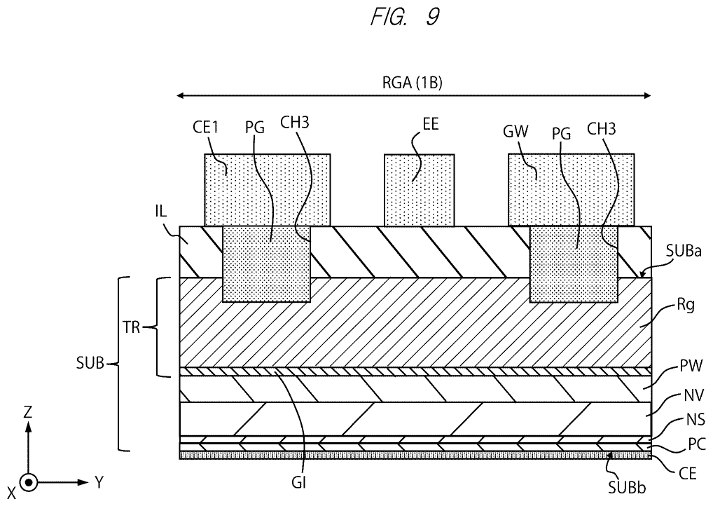

FIGS. 4 and 5 are plan views of the resistance element region RGA region shown in FIG. 3. FIG. 8 is a cross-sectional view taken along the line C-C of FIG. 4. FIG. 9 is a cross-sectional view taken along the line D-D FIG. 4.

As shown in FIG. 1, two resistance element regions RGA are formed in the semiconductor device 100 so as to sandwich the gate pad GP in the Y direction. FIGS. 3 and 4 show the structure of the resistance element region RGA located below the gate pad GP. The structure of the resistance element region RGA located above the gate pad GP has the same structure as in FIGS. 3 and 4, and the two resistance element regions RGA are in a line symmetrical relationship in the Y direction with respect to the X axis passing through the center of the gate pad GP.

As shown in FIG. 3, the semiconductor device 100 includes, in the X direction, the cell region 1A and a peripheral region 1B that is adjacent to the cell region 1A. The peripheral region 1B is formed in the well region PW in plan view.

As shown in FIG. 3, the peripheral region 1B has the gate pad GP and the resistance element region RGA arranged below the gate pad GP (in the negative direction of the Y direction). The gate pad GP has a quadrangle (such as square or rectangle) in plan view and has an opening OPG at its center.

A gate pad wiring GPW (which is assumed to be a part of the gate pad GP) is connected to the gate pad GP, and the gate pad wiring GPW extends to the resistance element region RGA. The gate pad wiring GPW is a wiring extending from the gate pad GP, and the wiring width of the gate pad wiring GPW is smaller than the length of the side of the gate pad GP (for example, the side from which the gate pad wiring GPW protrudes). The gate wiring GW is arranged around the gate pad GP and the resistance element region RGA and extends to the resistance element region RGA.

The resistance element region RGA is formed in the well region PW in plan view. A resistance element Rg exists in the resistance element region RGA, and the gate pad wiring GPW, the gate wiring GW (connected to a gate inspection pad GIP), and the first conductive member CE1 exist in the positive direction of Z viewed from the resistance element Rg. A part of the emitter electrode EE extends in a gap among the gate pad GP, gate wiring GW, and first conductive member CE1 elements in the resistance element region RGA. As already described above, the plan views of FIG. 3 and other drawings do not accurately show the positional relationship of the components in the up and down directions. See the cross-sectional views of FIGS. 8 and 9 for the positional relationship of the components in the resistance element region RGA in the up and down directions. The resistance element Rg, the gate pad GP (gate pad wiring GPW), the gate wiring GW, and the first conductive member CEL are electrically connected by the contact member PG formed in the contact hole CH3.

The resistance element Rg shown in FIG. 3 is the integral type resistance element formed through the insulating film inside the trench that forms the closed path (having the endless loop shape) in plan view, but will be explained while being divided into first extended part P1 to seventh extended part P7 and a first connecting part CP1 as shown in FIG. 4 for convenience of explanation. The first and second extended parts P1 and P2 extend in the Y direction and are separated from each other in the X direction. The first connecting part CP1 electrically connects one end of the first extended part P1 to one end of the second extended part P2. The third and fourth extended parts P3 and P4 extend in the Y direction, are separated from each other in the X direction, and are arranged between the first and second extended parts in plan view. The fifth extended part P5 extends in the X direction and electrically connects one end of the third extended part P3 to one end of the fourth extended part P4. The sixth extended part P6 extends in the X direction and electrically connects the other end of the first extended part P1 to the other end of the third extended part P3. The seventh extended part P7 extends in the X direction and electrically connects the other end of the second extended part P2 to the other end of the fourth extended part P4. Since the other end of the first extended part P1 and the other end of the second extended part P2 are electrically connected by the third to seventh extended parts P3 to P7, the third to seventh extended parts P3 to P7 are sometimes collectively called a second connecting part CP2. As already described above, the trench may be formed so that the width of the trench in plan view is made narrow at a border that is the folded portion of the loop shape, mainly from the viewpoint of the embedding property of polysilicon. In the first embodiment, the widths of the first to fourth extended parts P1 to P4 extending in the Y direction (width in the X direction in plan view) are set to 0.8 μm (micrometer), and the widths of the fifth to seventh extended parts P5 to P7 extending in the X direction and the width of the first connecting part CP1 (width in the Y direction in plan view) are set to 0.4 μm (micrometer).

As shown in FIG. 5, the resistance element Rg formed inside the trench is electrically connected to the first to eighth contact members CM1 to CM8. As shown in FIGS. 3 to 5, the first and second contact members CM1 and CM2 electrically connect the gate pad GP to the first and second extended parts P1 and P2, the third and fourth contact members CM3 and CM4 electrically connect the gate wiring GW to the third and fourth extended parts P3 and P4, the fifth contact member CM5 electrically connects the first conductive member CE1 and the first extended part P1, the sixth contact member CM6 electrically connects the first conductive member CE1 to the third extended part P3, the seventh contact member CM7 electrically connects the first conductive member CE1 to the fourth extended part P4, and the eighth contact member CM8 electrically connects the first conductive member CE1 to the second extended part P2. As shown in FIGS. 8 and 9, each contact member penetrating the interlayer insulating film IL electrically connects any of the gate pad GP, gate wiring GW, and first conductive member CE1 that are formed on the interlayer insulating film IL to the resistance element Rg formed in the p-type well region PW.

### Features of First Embodiment

Since the resistance element Rg having the configurations shown in FIGS. 3 to 5, 8, and 9 is provided, The resistance of the resistance element Rg against the electromigration can be Specifically, when the first conductive member CE1 improved. and fifth to eighth contact members CM5 to CM8 are not provided, if at least a part of the current flowing through the narrow-width sixth and seventh extended parts P6 and P7 is bypassed so as to flow through the first conductive member CE1, the current flowing through the sixth and seventh extended parts P6 and P7 can be decreased to thereby reduce the influence of the electromigration in the sixth and seventh extended parts P6 and P7. The current path formed when the current flows from the gate pad GP to the gate wiring GW will be described in detail below.

First, a current path formed when the first conductive member CE1 and the fifth to eighth contact members CM5 to CM8 are not provided in the resistance element region RGA shown in FIG. 3 and other drawings will be described. The current from the gate pad GP flows through the contact member CM1 to the first extended part P1 of the resistance element Rg, and then through the sixth extended part P6, the third extended part P3, and the third contact member CM3 to the gate wiring GW. At the same time, the current from the gate pad GP flows through the contact member CM2 to the second extended part P2 of the resistance element Rg, and then through the seventh extended part P7, the fourth extended part P4, and the fourth contact member CM4 to the gate wiring GW. Since both paths extend through the narrow-width sixth or seventh extended part and do not include the bypass path for bypassing the current flowing through the sixth and seventh extended parts P6 and P7, the resistance element Rg in the narrow-width sixth and seventh extended parts P6 and P7 may be deteriorated in course of time particularly by the influence of electromigration.

Next, as shown in FIG. 3 and other drawings, a current path formed when the first conductive member CE1 and the fifth to eighth contact members CM5 to CM8 are provided in the resistance element region RGA will be described as a first embodiment. The current from the gate pad GP is branched into current that flows from the first extended part P1 through the sixth extended part P6 into the third extended part and current that flows through the first contact member CM1 to the first extended part P1 of the resistance element Rg, and then flows from the first extended part P1 through the fifth contact member CM5 to the first conductive member CE1 and then flows through the sixth contact member CM6 to the third extended part. That is, if the first conductive member CE1 and the fifth to eighth contact members CM5 to CM8 are not provided, at least a part of the current flowing to the sixth extended part P6 is bypassed to the first conductive member CE1. At the same time, the current from the gate pad GP is branched into current that flows from the second extended part P2 through the seventh extended part P7 to the fourth extended part and current that flows through the contact member CM2 into the second extended part P2 of the resistance element Rg, and then flows from the second extended part P2 through the eighth contact member CM8 to the first conductive member CE1, and then flows through the seventh contact member CM7 to the fourth extended part. That is, if the first conductive member CE1 and the fifth to eighth contact members CM5 to CM8 are not provided, at least a part of the current flowing to the seventh extended part P7 is bypassed to the first conductive member CE1. The current flowing to the third extended part P3 and the current flowing to the fourth extended part P4 flows through the third contact member CM3 and the fourth contact member CM4, respectively, to the gate wiring GW. As described above, when the resistance element Rg, the first to eighth contact members CM1 to CM8, and the first conductive member CE1 of the first embodiment are used, at least a part of the current flowing into the narrow-width sixth and seventh extended parts P6 and P7 can be bypassed. This can improve the resistance of the resistance element Rg against the electromigration. In a preferable aspect, when the distance D1 (see FIG. 5) between the fifth to eighth contact members CM5 to CM8 and the sixth and seventh extended parts P6 and P7 is adjusted so that a ratio of the electrical resistance value between the bypass path and the non-bypass path is 1:1, an amount of the current flowing to the narrow-width sixth and seventh extended parts P6 and P7 can be made half an amount of the current flowing to the sixth and seventh extended parts P6 and P7 in the case without the bypass path.

In the configuration of the first embodiment, the ratio of the amount between the current flowing in the bypass path from the first extended part P1 through the fifth contact member CM5, the first conductive member CE1, and the sixth contact member CM6 to the third extended part P3, and the current flowing in the non-bypass path flowing from the first extended part P1 through the sixth extended part P6 to the third extended part P3 corresponds to the ratio of the electrical resistance of the two paths. Similarly, the ratio of the amount between the current flowing in the bypass path flowing from the second extended part P2 through the eighth contact member CM8, the first conductive member CE1, and the seventh contact member CM7 to the fourth extended part P4 and the amount of the current flowing in the non-bypass path flowing from the second extended part P2 through the seventh extended part P7 to the fourth extended part P4 corresponds to the ratio of the electrical resistance of the two paths. That is, if the path length of the non-bypass path is extremely short while the electrical resistance of the non-bypass path is extremely smaller than the electrical resistance of the bypass path, most of the current flows in the non-bypass path, and therefore, the effect of improving the resistance against the electromigration cannot be sufficiently obtained. In one aspect for adjusting the path length of the non-bypass path, the current flowing in the bypass path can be adjusted by adjusting the distance D1 shown above in FIG. 5, that is, the distance D1 from the fifth to eighth contact members CM5 to CM8 to the sixth and seventh extended parts P6 and P7 so as to be a predetermined distance or larger to adjust the electrical resistance of the non-bypass path to a predetermined value or larger. Also, if the first to eighth contact members CM1 to CM8 in the Y direction are extremely short, the current densities in the first to eighth contact members CM1 to CM8 are high, and the influence of electromigration in the first to eighth contact members CM1 to CM8 is large. Meanwhile, the current flowing through the first to eighth contact members CM1 to CM8 is concentrated on the center edge of the loop shape of the trench TR including the resistance element Rg. Therefore, if the first to eighth contact members CM1 to CM8 in the Y direction are made extremely long, the first to eighth contact members CM1 to CM8 include a large region where no current flows, and therefore, the first to eighth contact members CM1 to CM8 cannot be used efficiently. In view of the above, the lengths of the first to eighth contact members CM1 to CM8 in the Y direction are preferably made within a predetermined range. In one example, the lengths of the first to eighth contact members CM1 to CM8 in the Y direction can be set to 20 μm (micrometer).

### Modification Example of First Embodiment

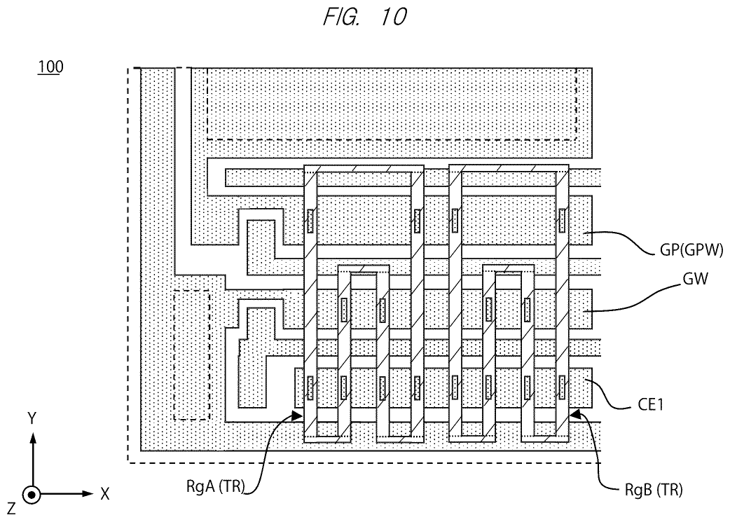

FIG. 10 is a plan view of a principal part showing a modification example of the semiconductor device in the first embodiment. Two sets of resistance elements Rg, first to eighth contact members CM1 to CM8 described with reference to FIG. 3 and other drawings are formed to separate in the X direction. The configuration of each of the two sets is the same as that described above in the first embodiment. The configuration shown in FIG. 10 corresponds to a configuration in which two sets of current paths from the gate pad GP to the gate wiring GW are provided in parallel as described with reference to FIG. 3 and other drawings. Based on the same principle as that described with reference to FIG. 3 and other drawings, the resistance of the resistance element Rg in each of the two sets against the electromigration can be improved by decrease of the current flowing in the narrow-width sixth and seventh extended parts P6 and P7 in each of the two sets of resistance elements RgA and RgB. Note that the number of the sets of the resistance element Rg and the first to eighth contact members CM1 to CM8 to be formed may be any number of three or more. That is, a plurality of sets of the resistance element Rg formed in the trench TR through the insulating film GI and the first to eighth contact members CM1 to CM8 may be formed, the sets may be arranged to separate from each other in the X direction in plan view, the gate pad wiring GPW included in the gate pad GP may be formed to overlap the first and second contact members CM1 and CM2 in each of the plurality of the sets in plan view, the gate wiring GW may be arranged to overlap the third and fourth contact members CM3 and CM4 in each of the plurality of the sets in plan view, and the first conductive member CE1 may be arranged to overlap the fifth to eighth contact members CM5 to CM8 in each of the plurality of the sets in plan view.

### Second Embodiment

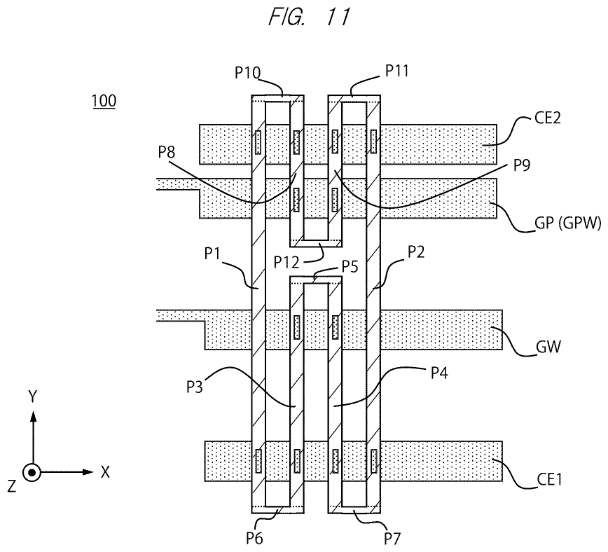

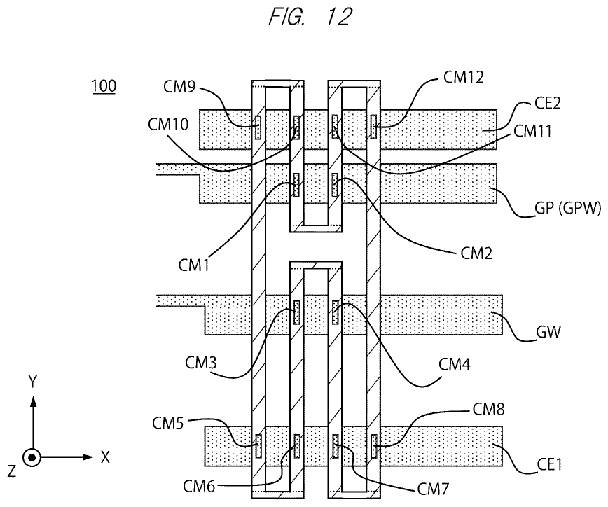

Each of FIGS. 11 and 12 is a plan view of a principal part showing a semiconductor device 100 in a second embodiment. In the second embodiment, the shape of the resistance element Rg differs from that of the first embodiment, and the layout and the number of the contact members CM also differ from those of the first embodiment. Furthermore, in the second embodiment, a second conductive member CE2 (such as a flat plate type conductive pad) is provided. The second conductive member CE2 is also the same as the first conductive member CE1 in that the CE2 is arranged on the interlayer insulating film IL and includes the barrier metal film and the conductive film formed on the barrier metal film. In the following description, differences from the first embodiment will be mainly explained, and points in common with the first embodiment will be omitted as appropriate.

As shown in FIG. 11, the first and second extended parts P1 and P2 extend in the Y direction and are arranged to separate from each other in the X direction. The third and fourth extended parts P3 and P4 extend in the Y direction, are separated from each other in the X direction, and are arranged between the first and second extended parts in plan view. The fifth extended part P5 extends in the X direction and electrically connects one end of the third extended part P3 to one end of the fourth extended part P4. The sixth extended part P6 extends in the X direction and electrically connects the other end of the first extended part P1 to the other end of the third extended part P3. The seventh extended part P7 extends in the X direction and electrically connects the other end of the second extended part P2 to the other end of the fourth extended part P4. The eighth and ninth extended parts P8 and P9 extend in the Y direction, are separated from each other in the X direction, and are arranged between the first extended part P1 and the second extended part P2 in plan view. The tenth extended part P10 extends in the X direction and electrically connects one end of the first extended part P1 and one end of the eighth extended part P8. The eleventh extended part P11 extends in the X direction and electrically connects one end of the second extended part P2 to one end of the ninth extended part P9. The twelfth extended part P12 extends in the X direction and electrically connects the other end of the eighth extended part P8 to the other end of the ninth extended part P9. Since the eighth to twelfth extended parts P8 to P12 electrically connect one end of the first extended part P1 and one end of the second extended part P2, the eighth to twelfth extended parts P8 to P12 are collectively called the first connecting part CP1. Since the third to seventh extended parts P3 to P7 electrically connect the other end of the first extended part P1 to the other end of the second extended part P2, the third to seventh extended parts P3 to P7 are collectively called the second connecting part CP2. In the second embodiment, the widths of the first to fourth, eighth, and ninth extended parts P1 to P4, P8, and P9 extending in the Y direction (widths in the X direction in plan view) are set to 0.8 μm (micrometer), and the widths of the fifth to seventh, tenth to twelfth extended parts P5 to P7 and P10 to P12 extending in the X direction (widths in the Y direction in plan view) are set to 0.4 μm (micrometer).

As shown in FIG. 12, the resistance element Rg formed inside the trench is electrically connected to the first contact member CM1 to the twelfth contact member CM12. The first and second contact members CM1 and CM2 electrically connect the gate pad GP and the eighth and ninth extended parts P8 and P9, respectively. The third and fourth contact members CM3 and CM4 electrically connect the gate wiring GW and the third and fourth extended parts P3 and P4, respectively. The fifth contact member CM5 electrically connects the first conductive member CE1 and the first extended part P1. The sixth contact member CM6 electrically connects the first conductive member CE1 and the third extended part P3. The seventh contact member CM7 electrically connects the first conductive member CE1 and the fourth extended part P4. The eighth contact member CM8 electrically connects the first conductive member CE1 and the second extended part P2. The ninth contact member CM9 electrically connects the second conductive member CE2 and the first extended part P1. The tenth contact member CM10 electrically connects the second conductive member CE2 and the eighth extended part P8. The eleventh contact member CM11 electrically connects the second conductive member CE2 and the ninth extended part P9. The twelfth contact member CM12 electrically connects the second conductive member CE2 and the second extended part P2.

In the semiconductor device 100 shown in FIGS. 11 and 12, a current path passing through the fifth contact member CM5, the first conductive member CE1, and the sixth contact member CM6 is formed as the bypass path for the current path passing through the sixth extended part P6. Also, a current path passing through the seventh contact member CM7, the first conductive member CE1, and the eighth contact member CM8 is formed as the bypass path for the current path passing through the seventh extended part P7. Also, a current path passing through the ninth contact member CM9, the second conductive member CE2, and the tenth contact member CM10 is formed as the bypass path for the current path passing through the 10th extended part P10. Also, a current path passing through the eleventh contact member CM11, the second conductive member CE2, and the twelfth contact member CM12 is formed as the bypass path for the current path passing through the eleventh extended part P11. Accordingly, since the current flowing through the narrow-width sixth, seventh, tenth, and eleventh extended parts P6, P7, P10, and P11 is decreased, the influence of electromigration on these extended parts is reduced.

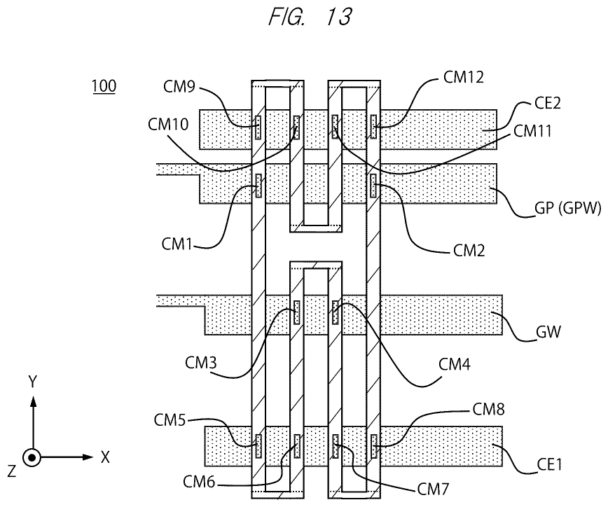

Note that the shape of the resistance element Rg in the second embodiment is also discriminative in that the electrical resistance of the current path passing from the gate pad GP to the gate wiring GW can be adjusted by the change in the position of the contact member CM along with the securement of the resistance against the electromigration. The following is description for an example in which the electrical resistance of the resistance element Rg is changed from the electrical resistance of the resistance element Rg of FIGS. 11 and 12 by the change in the position of the contact member CM, with reference to FIGS. 13 to 15.

### First Modification Example of Second Embodiment

FIG. 13 is a plan view of a principal part showing a first modification example of the semiconductor device in the second embodiment. In comparison with the configurations of FIGS. 11 and 12, the positions of the first and second contact members CM1 and CM2 are different, and the first and second contact members CM1 and CM2 electrically connect the gate pad GP and the first and second extended parts P1 and P2, respectively.

The paths of the current flowing from the gate pad GP to the gate wiring GW (paths including the bypass path) in the configurations of FIGS. 11 and 12 are the following two parallel paths that are:
(1) the path leading to the gate wiring GW through the first contact member CM1, the eighth extended part P8, the tenth contact member CM10, the second conductive member CE2, the ninth contact member CM9, the first extended part P1, the fifth contact member CM5, the first conductive member CE1, the sixth contact member CM6, the third extended part P3, and the third contact member CM 3
(2) the path leading to the gate wiring GW through the second contact member CM2, the ninth extended part P9, the eleventh contact member CM11, the second conductive member CE2, the twelfth contact member CM12, the second extended part P2, the eighth contact member CM8, the first conductive member CE1, the seventh contact member CM7, the fourth extended part P4, and the fourth contact member CM4.

The paths of the current flowing from the gate pad GP to the gate wiring GW (paths including the bypass path) in the configurations of FIG. 13 are the following two parallel paths that are:
(1) the path leading to the gate wiring GW through the first contact member CM1, the first extended part P1, the fifth contact member CM5, the first conductive member CE1, the sixth contact member CM6, the third extended part P3, and the third contact member CM3
(2) the path leading to the gate wiring GW through the second contact member CM2, the second extended part P2, the eighth contact member CM8, the first conductive member CE1, the seventh contact member CM7, the fourth extended part P4, and the fourth contact member CM4.

The current paths in the configuration of FIG. 13 are shorter that those in the configurations of FIGS. 11 and 12. In other words, the electrical resistance of the current paths passing from the gate pad GP to the gate wiring GW can be reduced by change in the positions of the first and second contact members CM1 and CM2 from those in the configurations of FIGS. 11 and 12.

### Second Modification Example of Second Embodiment

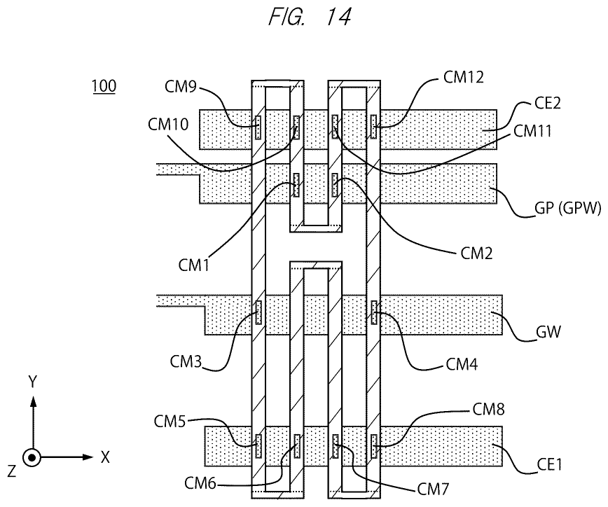

FIG. 14 is a plan view of a principal part showing a second modification example of the semiconductor device in the second embodiment. In comparison with the configurations of FIGS. 11 and 12, the positions of the third and fourth contact members CM3 and CM4 are different, and the third and fourth contact members CM3 and CM4 electrically connect the gate wiring GW and the first and second extended part P1 and P2, respectively.

The paths of the current flowing from the gate pad GP to the gate wiring GW (paths including the bypass path) in the configurations of FIG. 14 are the following two parallel paths that are:
(1) the path leading to the gate wiring GW through the first contact member CM1, the eighth extended part P8, the tenth contact member CM10, the second conductive member CE2, the ninth contact member CM9, the first extended part P1, and the third contact member CM3
(2) the path leading to the gate wiring GW through the second contact member CM2, the ninth extended part P9, the eleventh contact member CM11, the second conductive member CE2, the twelfth contact member CM12, the second extended part P2, and the fourth contact member CM4.

The current paths in the configuration of FIG. 14 are shorter that those in the configurations of FIGS. 11 and 12. If the distance between the first conductive member CE1 and the gate wiring GW (distance in the Y direction) is larger than the distance between the second conductive member CE2 and the gate pad GP (distance in the Y direction), the current paths in the configuration of FIG. 14 are shorter than those in the configuration of FIG. 13. In other words, the electrical resistance of the current paths passing from the gate pad GP to the gate wiring GW can be reduced by change in the positions of the third and fourth contact members CM3 and CM4 from those of the configuration of FIGS. 11 and 12.

### Third Modification Example of Second Embodiment

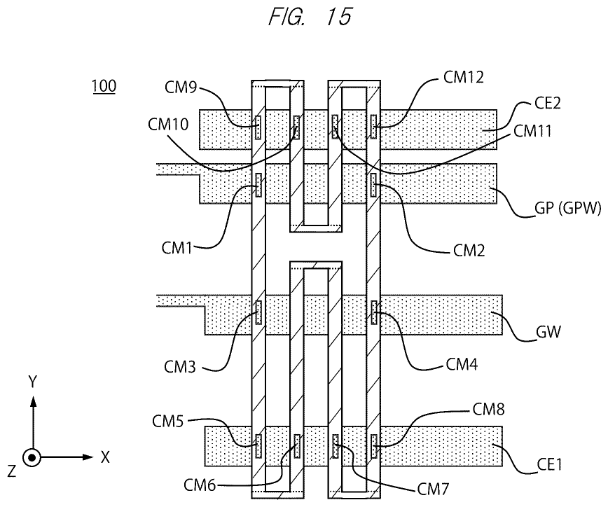

FIG. 15 is a plan view of a principal part showing a third modification example of the semiconductor device in the second embodiment. In comparison with the configurations of FIGS. 11 and 12, the positions of the first to fourth contact members CM1 to CM4 are different. The first and second contact members CM1 and CM2 electrically connect the gate pad GP and the first and second extended part P1 and P2, respectively. The third and fourth contact members CM3 and CM4 electrically connect the gate wiring GW and the first and second extended part P1 and P2, respectively.

The paths of the current flowing from the gate pad GP to the gate wiring GW (paths including the bypass path) in the configurations of FIG. 15 are the following two parallel paths that are:
(1) the path leading to the gate wiring GW through the first contact member CM1, the first extended part P1, and the third contact member CM3
(2) the path leading to the gate wiring GW through the second contact member CM2, the second conductive member CE2, the twelfth contact member CM12, the second extended part P2, and the fourth contact member CM4.

The current paths in the configuration of FIG. 15 are shorter that those in the configurations of FIGS. 11, 12, 13 and 14. In other words, the electrical resistance of the current paths passing from the gate pad GP to the gate wiring GW can be reduced by change in the positions of the first to fourth contact members CM1 to CM4 from those of the configuration of FIGS. 11 and 12.

### Third Embodiment

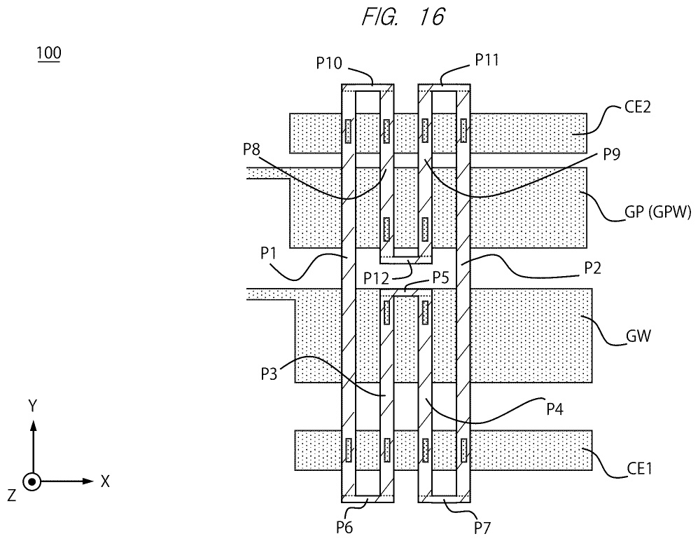

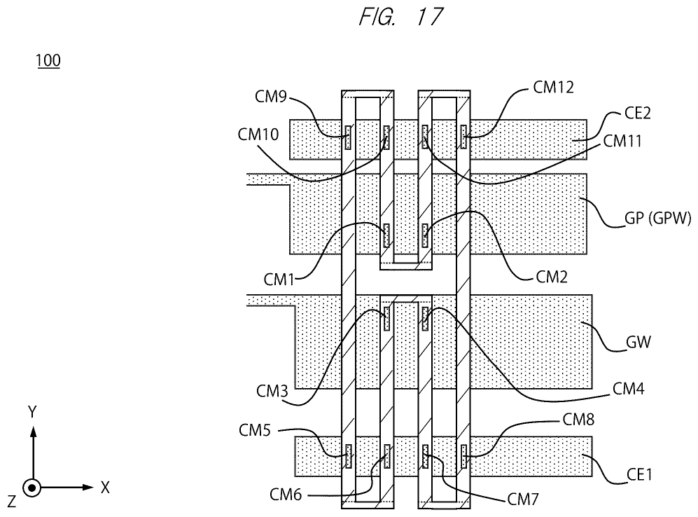

Each of FIGS. 16 and 17 is a plan view of a principal part showing a semiconductor device 100 in the third embodiment. In the third embodiment, the shape of the resistance element Rg is similar to that of the second embodiment (FIGS. 11 and 12), and the extended parts and contact members through which the current paths pass from gate pad GP to the gate wiring GW are also the same as those of the second embodiment. However, the widths of gate pad GP and the gate wiring GW in the Y direction are larger than those in the second embodiment. The adoption of the configuration shown in FIGS. 16 and 17 makes large margins for the change in the positions of the first and second contact members CM1 and CM2 in the Y direction along with the securement of the electrical connection with the gate pad GP and for the change in the positions of the third and fourth contact members CM3 and CM4 in the Y direction along with the securement of the electrical connection with the gate wiring GW. By such positional change, the electrical resistance of the current path passing from the gate pad GP to the gate wiring GW can be changed.

### Modification Example of Third Embodiment

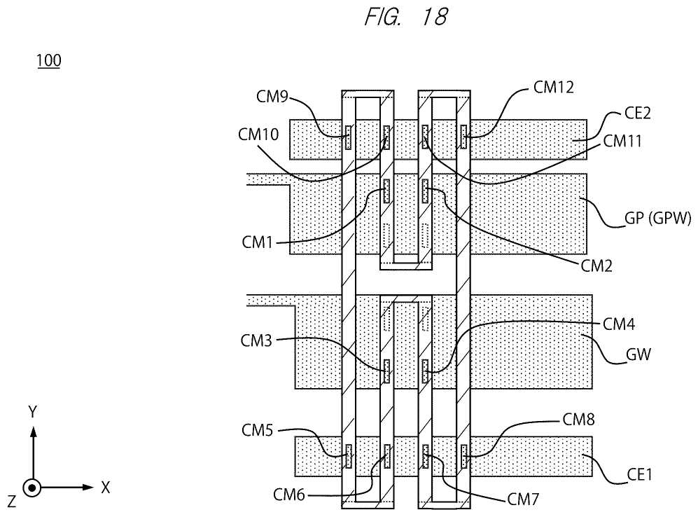

FIG. 18 is a plan view of a principal part showing a modification example of the semiconductor device in the third embodiment. In comparison with the configurations of FIGS. 16 and 17, the positions of the first and second contact members CM1, CM2 are moved to the positive direction of the Y direction, and the positions of the third and fourth contact members CM3, CM4 are moved to the negative direction of the Y direction. By these movements, the current path passing from the gate pad GP to the gate wiring GW is shortened, and the electrical resistance of the current path in the configuration of FIG. 18 is decreased than the electrical resistance of the current path in the configurations of FIGS. 16 and 17.

### Fourth Embodiment

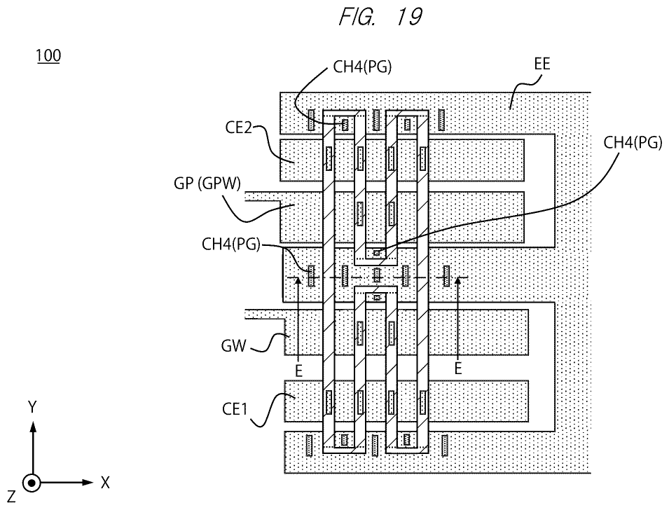

FIG. 19 is a plan view of a principal part showing a semiconductor device 100 in the fourth embodiment. In the fourth embodiment, the shape of the resistance element Rg is similar to that of the second embodiment (FIGS. 11 and 12), and the extended parts and contact members through which the current paths pass from gate pad GP to the gate wiring GW are also the same as those of the second embodiment. However, a well contact member (contact member (plug) PG) for electrically connecting the emitter electrode EE and the well region PW is formed in the well contact hole CH4.

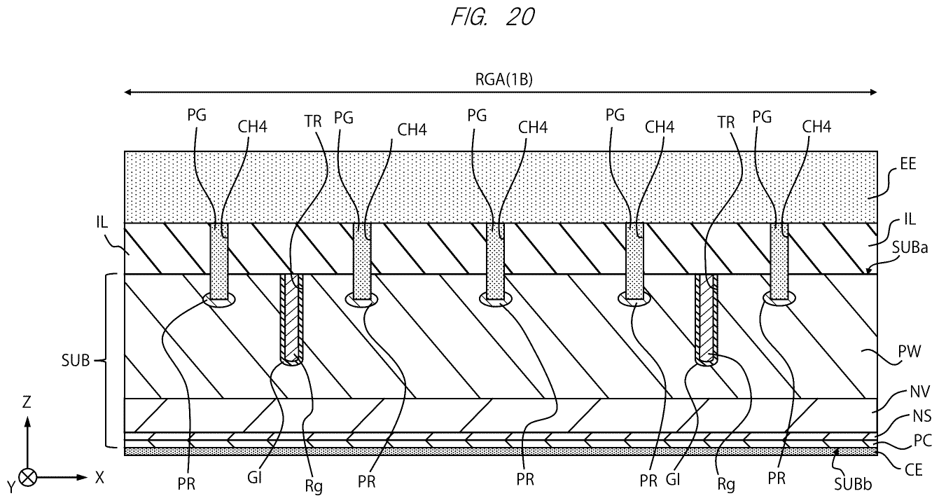

FIG. 20 is a cross-sectional view taken along the line E-E in the plan view of FIG. 19. Five well contact members (contact members (plugs) PG) electrically connect the emitter electrode EE and the well region PW. By such a configuration, the potential difference of the well region PW between the regions of the trench TR on the positive and negative sides of the X direction can be decreased. Further, the dielectric breakdown of the gate insulating film GI in the trench TR in which the resistance element Rg is embedded can be prevented.

### Method of Manufacturing Semiconductor Device

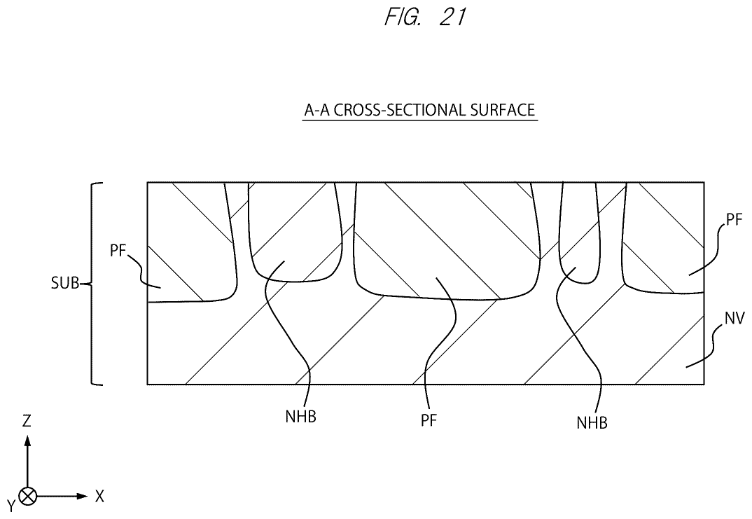

Each manufacturing step included in the method of manufacturing the semiconductor device 100 in the e first embodiment will be described below with reference to FIGS. 21 to 35.

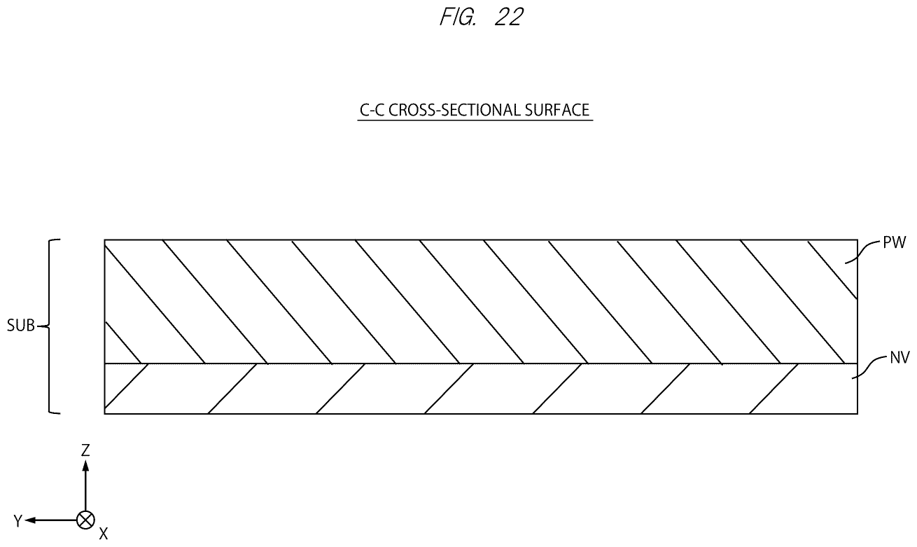

First, a semiconductor substrate SUB having an n-type drift region NV is prepared. The semiconductor substrate SUB is made of n-type silicon. Note that the semiconductor substrate SUB may be a stacked body of an n-type silicon substrate and an n-type silicon layer grown on the silicon substrate while being doped with phosphorus (P) by an epitaxial growth method. Next, as shown in FIG. 21, an n-type hole barrier region NHB is formed in a region 1A of the semiconductor substrate SUB close to the upper surface side of the semiconductor substrate SUB by a photolithography technique and an ion implantation method. Next, a p-type floating region PF is formed in the region 1A of the semiconductor substrate SUB close to the upper surface side of the semiconductor substrate SUB by a photolithography technique and an ion implantation method (FIG. 21), and at the same time, a p-type well region PW is formed in a region 2A of the semiconductor substrate SUB as shown in FIG. 22. The floating region PF is physically separated from the well region PW.

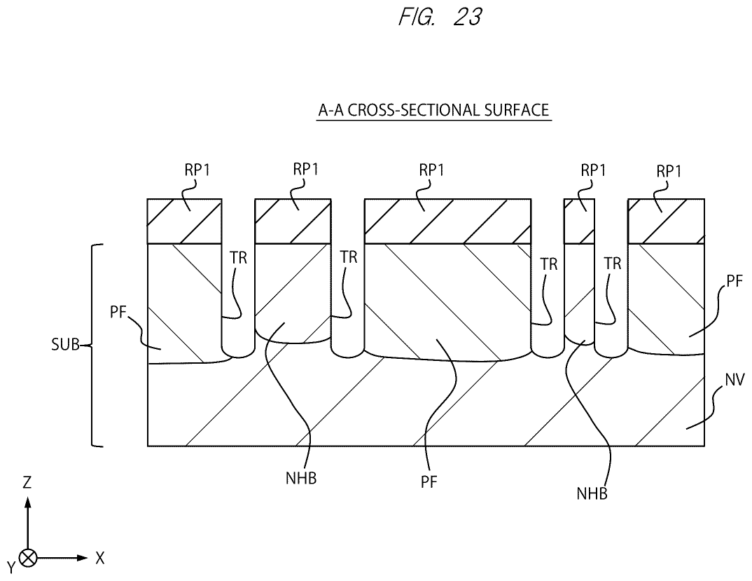

Subsequently, as shown in FIG. 23, a pair of trenches TR are formed in the semiconductor substrate SUB of the active cell AC and the inactive cell IAC in the region 1A close to the upper surface side of the semiconductor substrate SUB. First, a resist pattern RP1 is formed on the upper surface of the semiconductor substrate SUB in the region 1A so as to cover the region 2A and a part of the region 1A. Next, an anisotropic etching process is performed to the semiconductor substrate SUB in the region 1A while using the resist pattern RP1 as a mask. Thereby, a plurality of trenches TR are formed in the semiconductor substrate SUB in the region 1A. Thereafter, the resist pattern RP1 is removed by ashing process.

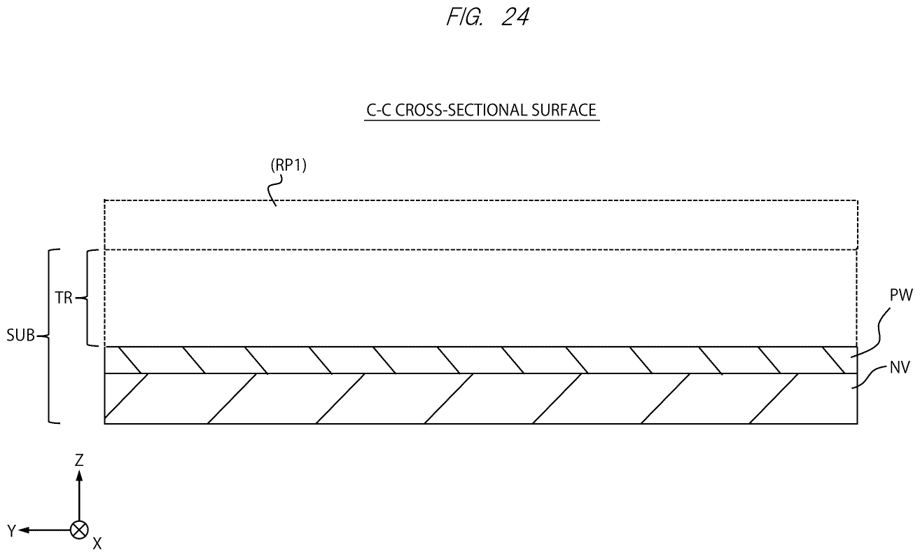

Concurrently with the step shown in FIG. 23, a trench TR (see FIG. 3) forming a closed path in plan view for forming the resistance element Rg is formed in the semiconductor substrate SUB in the region 1B, especially in the well region PW, close to the upper surface side of the semiconductor substrate SUB, as shown in FIG. 24. The method of forming the trench TR is the same as the method of forming the trench TR in the region 1A.

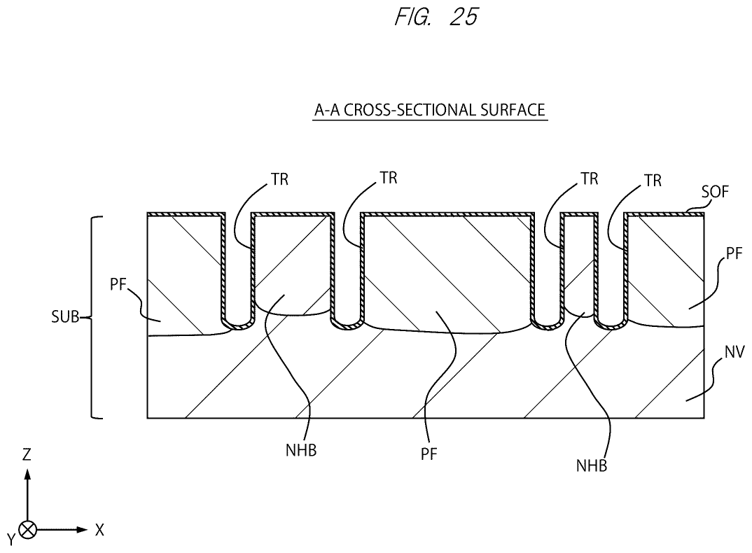

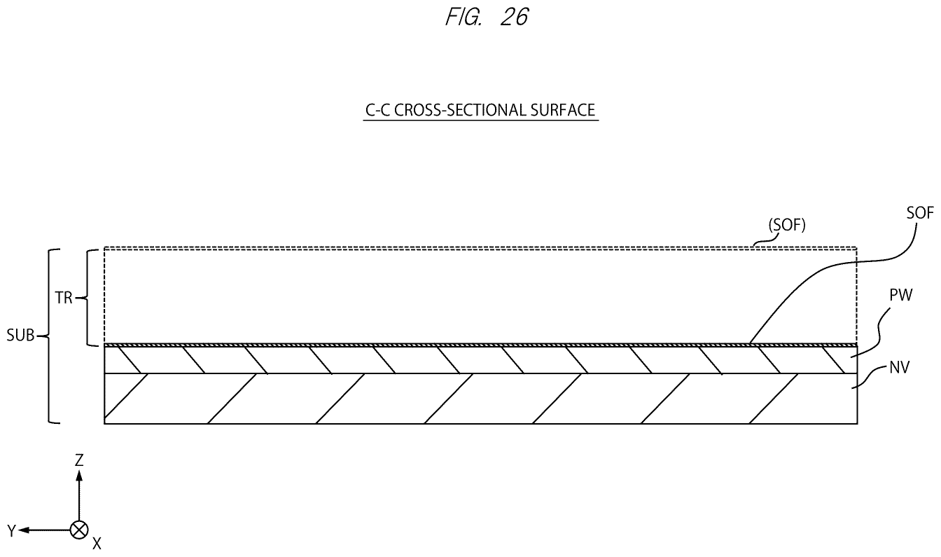

As shown in FIGS. 25 and 26, a sacrificial oxide film SOF is formed inside the trench TR and on the upper surface of the semiconductor substrate SUB. Thereby, a damaged layer formed in the semiconductor substrate SUB is removed. After that, the sacrificial oxide film SOF is removed by, for example, isotropic etching process using a solution containing hydrofluoric acid.

Note that the sacrificial oxide film SOF is formed by heating the semiconductor substrate SUB. This heat process is performed in, for example, an atmosphere filled with oxygen gas, and under conditions at 1100° C. for 30 minutes or longer and 60 minutes or shorter. By this heat process, the impurities in the hole barrier region NHB, floating region PF, and well region PW are diffused.

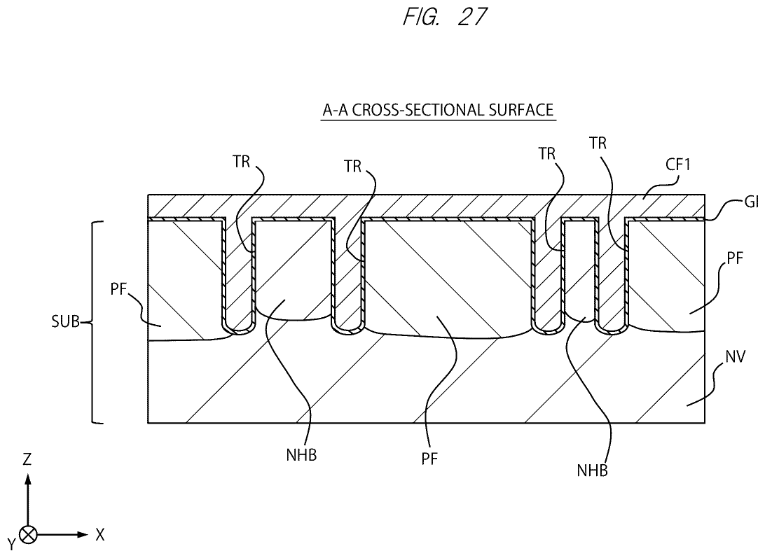

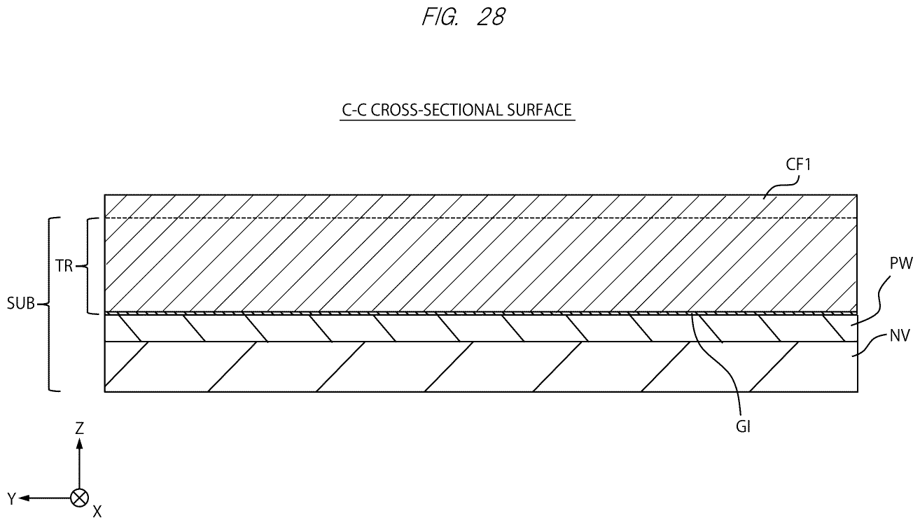

Next, as shown in FIGS. 27 and 28, the gate insulating film GI and conductive film CF1 are formed. First, the gate insulating film GI is formed inside the trench TR and on the upper surface of the semiconductor substrate SUB by a thermal oxidation method.

Next, the conductive film CF1 is formed inside the trench TR and on the upper surface of the semiconductor substrate SUB so as to fill the inside of the trench TR through the gate insulating film GI by, for example, a CVD method. The conductive film CF1 is, for example, a polycrystalline silicon film doped with an n-type impurity.

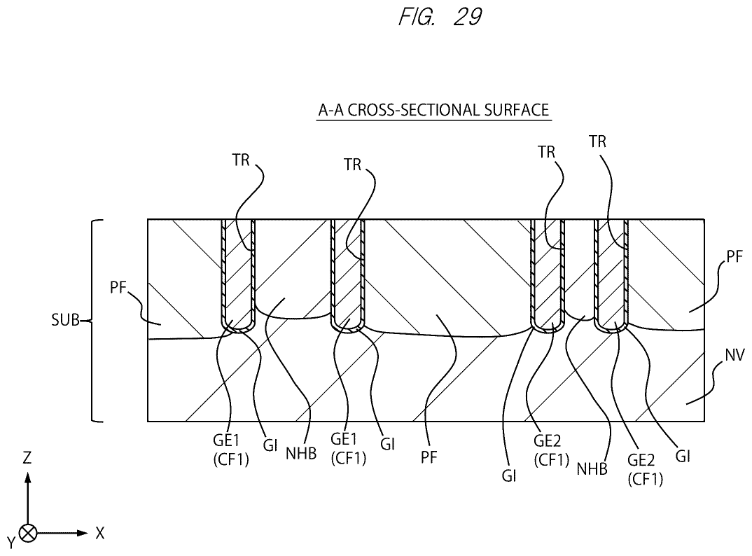

As shown in FIG. 29, a gate insulating film GI and gate electrodes GE1 and GE2 are formed inside the trench TR. First, the conductive film CF1 formed outside the trench TR is removed by an anisotropic etching process. The conductive film CF1 formed inside the trench TR is left as the gate electrodes GE1 and GE2. Next, the gate insulating film GI formed outside the trench TR is removed by an isotropic etching process, an anisotropic etching process, or an etching process combining these etching processes.

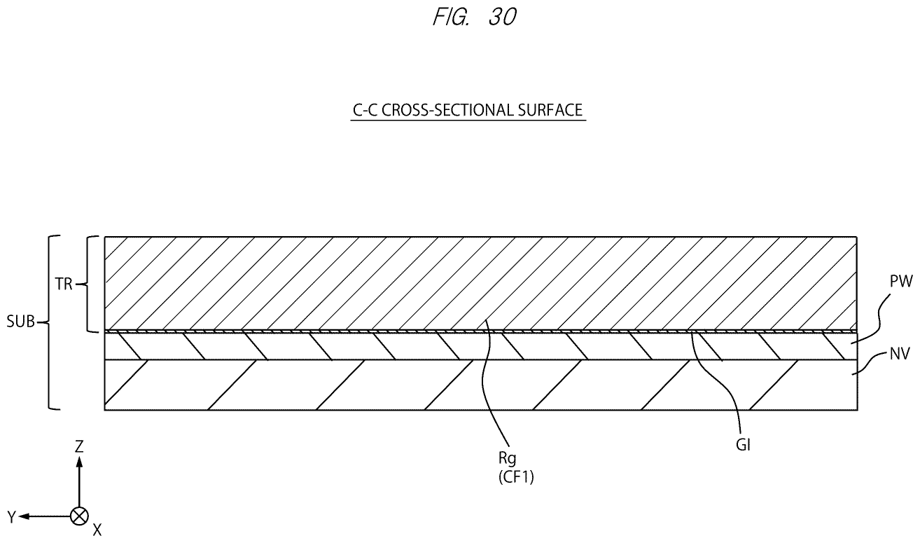

Concurrently with the step shown in FIG. 29, a resistance element Rg is formed inside the trench TR as shown in FIG. 30. First, the conductive film CF1 formed outside the trench TR is removed by an anisotropic etching process. The conductive film CF1 formed inside the trench TR is left as the resistance element Rg. Next, the gate insulating film GI formed outside the trench TR is removed by an isotropic etching process, an anisotropic etching process, or an etching process combining these etching processes.

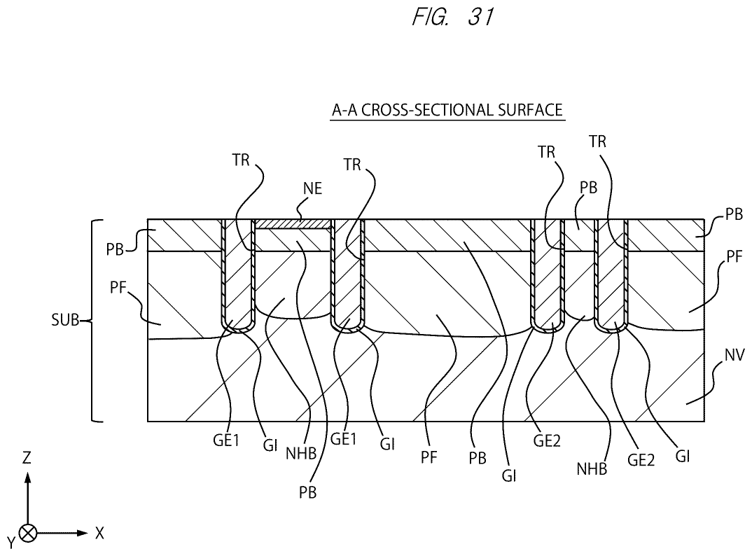

Next, as shown in FIG. 31, a p-type base region PB is formed inside the semiconductor substrate SUB in the region 1A (floating region PF and hole barrier region NHB) close to the upper surface side of the semiconductor substrate SUB by a photolithography technique and an ion implantation method. Next, an n-type emitter region NE is formed inside the base region PB by a photolithography technique and an ion implantation method. Subsequently, heat process is performed to the semiconductor substrate SUB to activate the impurity contained in each impurity region.

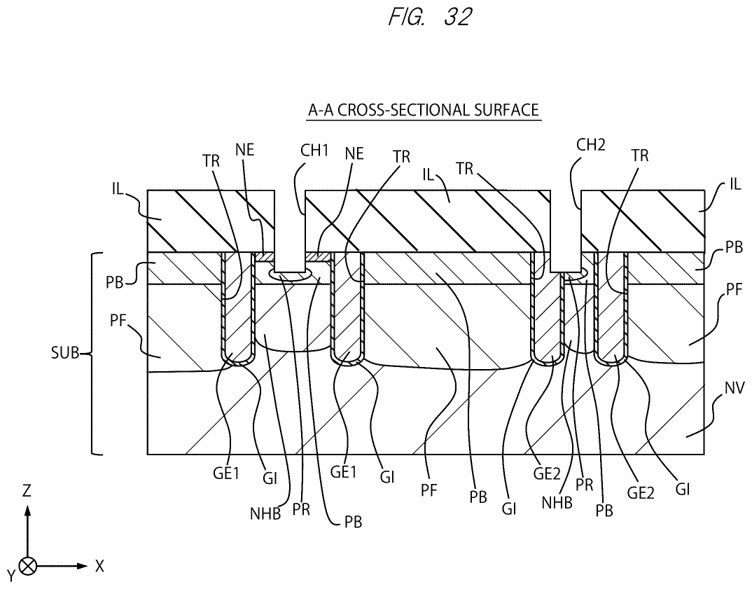

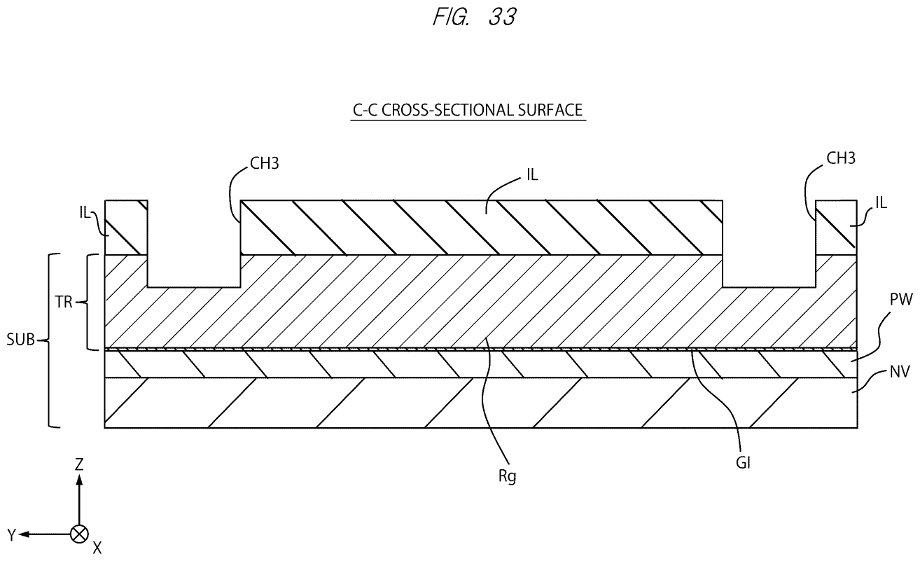

Next, as shown in FIGS. 32 and 33, an interlayer insulating film IL is formed on the upper surface of the semiconductor substrate SUB in the regions 1A and 2A so as to cover the trench TR in the region 1A and the resistance element Rg in the region 2A by, for example, a CVD method. Subsequently, a polishing process is performed to the interlayer insulating film IL in the regions 1A and 2A by a CMP method in order to planarize the upper surface of the interlayer insulating film IL. Furthermore, contact holes CH1 to CH3 are formed in the interlayer insulating film IL in the regions 1A and 2A by a photolithography technique and an anisotropic etching process. Next, as shown in FIG. 32, a p-type high concentration diffusion region PR is formed on the bottoms of the contact holes CH1 and CH2 by an ion implantation method.

The contact hole CH1 penetrates the interlayer insulating film IL and the emitter region NE, and reaches the inside of the base region PB. The contact hole CH2 penetrates the interlayer insulating film IL, and reaches the inside of the base region PB. Also, the contact hole CH2 is formed so as to overlap the gate electrode GE2 in plan view. The contact hole CH3 (eight contact holes CH3 are formed to correspond to the first to eighth contact members CM1 to CM8 shown in FIG. 5) penetrates the interlayer insulating film IL, and reaches the inside of the resistance element Rg.

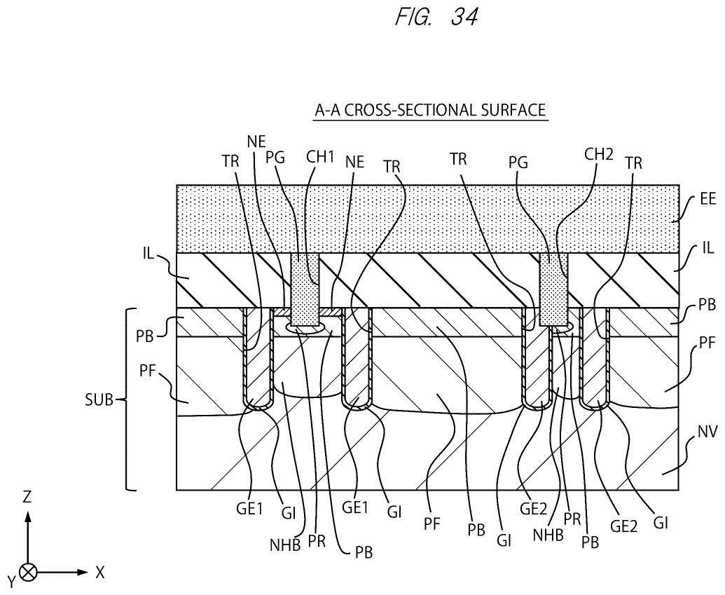

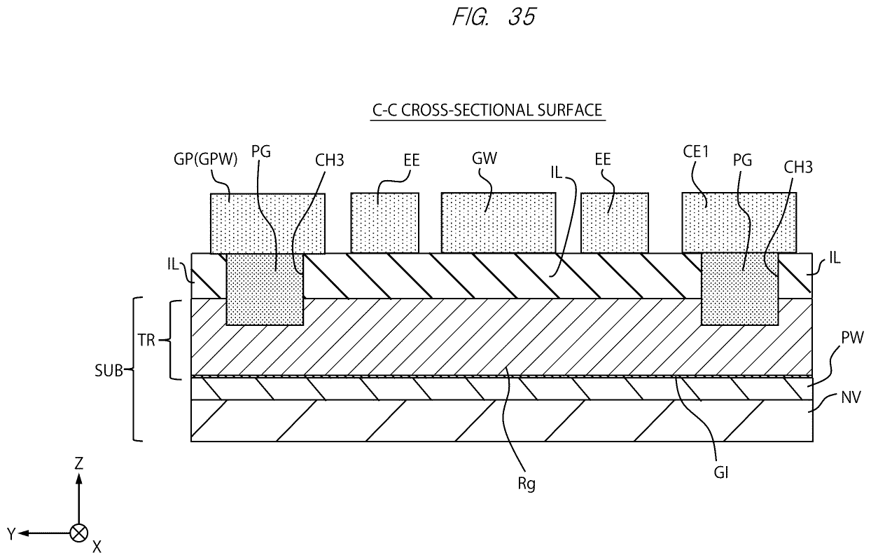

As shown in FIGS. 34 and 35, a contact member PG is formed inside each of the contact holes CH1 to CH3. First, a barrier metal film is formed inside each of the contact holes CH1 to CH3 and on the interlayer insulating film IL. The barrier metal film described above can be formed by, for example, a sputtering method of forming a titanium film in each of the contact holes CH1 to CH3 and on the interlayer insulating film IL, and, for example, a sputtering method of forming a titanium nitride film on the titanium film.

Next, a conductive film made of, for example, a tungsten film is formed on the barrier metal film so as to fill the inside of each of the contact holes CH1 to CH3 by, for example, a CVD method. Next, the conductive film and the above barrier metal film formed outside each of the contact holes CH1 to CH3 are removed by an anisotropic etching process. As a result, a contact member PG is formed so as to fill the inside of each of the contact holes CH1 to CH3.

Next, a gate pad GP (including a gate pad wiring GPW), a gate wiring GW, a first conductive member CE1, and an emitter electrode EE are formed on the interlayer insulating film IL. First, a TiW film is formed on the interlayer insulating film IL by, for example, a sputtering method, and then, an aluminum alloy film is formed on the TiW film by, for example, a sputtering method. Next, the TiW film and the aluminum alloy film are patterned by a photolithography technique and a dry etching process, thereby forming the gate pad GP, the gate wiring GW, the first conductive member CE1, and the emitter electrode EE.

Thereafter, the structure shown in FIGS. 3 to 9 is obtained by the following manufacturing step. First, an n-type field stop region NS and a p-type collector region PC are formed by ion implantation from the lower surface side of the semiconductor substrate SUB. After the ion implantation, the impurities contained in the field stop region NS and collector region PC are activated by laser annealing. Next, a metal film such as an Au film, Ni film, Ti film, or AlSi film is formed below the lower surface of the semiconductor substrate SUB by, for example, a sputtering method. This metal film serves as a collector electrode CE. The collector electrode CE may be a stacked film in which the metal films are stacked as appropriate.

The method of manufacturing the semiconductor device 100 in the second to fourth embodiments is roughly the same as the method described with reference to FIGS. 21 to 35. In order to form a second conductive member CE2, the second conductive member CE2 may be formed on the interlayer insulating film IL as similar to the first conductive member CE1. In order to form a well contact member (contact member PG) in the well contact hole CH4, as shown in FIGS. 33 to 35, after the formation of the contact holes CH1 to CH3, the well contact hole CH4 may be formed concurrently with the step of forming the contact member PG inside the contact holes CH1 to CH3, and the contact member PG may be formed inside the well contact hole CH4.

In the foregoing, the present invention has been concretely described on the basis of the embodiments. However, the present invention is not limited to the foregoing embodiments, and various modifications can be made within the scope of the present invention.

For example, in the above embodiments, the IGBT is exemplified as the device formed in the cell region 1A. However, the technique disclosed in the above embodiments is not limited to the IGBT but also applicable to a power MOSFET having a vertical trench gate structure.

Also, the material used for the semiconductor substrate SUB is not limited to silicon (Si), and silicon carbide (Sic), gallium nitride (GaN), gallium oxide (Ga₂O₃) or the like is also applicable. The n-type impurity may be, for example, phosphorus (P), arsenic (As) or the like, and the p-type impurity may be, for example, boron (B), Indium (In) or the like.

Also, various configurations described in the embodiments and the modification examples of the embodiments can be combined with each other. This specification describes, for example, the following configurations.

### STATEMENTS

### Statement 1

A semiconductor device includes:
a semiconductor substrate having a first main surface and a well region formed on the first main surface;
an interlayer insulating film formed on the first main surface;
a gate pad, a gate wiring, and a first conductive member formed on the interlayer insulating film;
a resistance element formed through an insulating film inside a trench that forms a closed path in plan view, the trench being formed in the well region; and
first to eighth contact members penetrating the interlayer insulating film and reaching the resistance element,
the resistance element includes:
first and second extended parts extending in a first direction in plan view and separating from each other in a second direction crossing the first direction in plan view;
a first connecting part electrically connecting one end of the first extended part and one end of the second extended part; and
a second connecting part electrically connecting the other end of the first extended part and the other end of the second extended part,
the first and second contact members each electrically connects the gate pad and the resistance element,
the third and fourth contact members each electrically connects the gate wiring and the resistance element, and
the fifth to the eighth contact member each electrically connects the first conductive member and the resistance element.

### Statement 2

In the semiconductor device according to the statement 1,

the second connecting part includes:
third and fourth extended parts extending in the first direction, separating from each other in the second direction, and being arranged between the first and second extended parts in plan view;
a fifth extended part extending in the second direction and electrically connecting one end of the third extended part and one end of the fourth extended part;
a sixth extended part extending in the second direction and electrically connecting the other end of the first extended part and the other end of the third extended part; and
a seventh extended part extending in the second direction and electrically connecting the other end of the second extended part and the other end of the fourth extended part,
the fifth contact member electrically connects the first conductive member and the first extended part,
the sixth contact member electrically connects the first conductive member and the third extended part,
the seventh contact member electrically connects the first conductive member and the fourth extended part, and
the eighth contact member electrically connects the first conductive member and the second extended part.

### Statement 3

In the semiconductor device according to the statement 1 or 2,
the third contact member electrically connects the gate wiring and the third extended part, and the fourth contact member electrically connects the gate wiring and the fourth extended part.

### Statement 4

In the semiconductor device according to any one of the statements 1 to 3,
each width of the first to fourth extended parts in the second direction in plan view is larger than each width of the fifth to seventh extended parts in the first direction in plan view.

### Statement 5

In the semiconductor device according to any one of the statements 1 to 4,
the fifth to eighth contact members separate by at least a predetermined distance from the sixth and seventh extended parts in the first direction.

### Statement 6

In the semiconductor device according to any one of the statements 1 to 5,
the first to eighth contact members each has a length within a predetermined range in the first direction.

### Statement 7

The semiconductor device according to any one of the statements 1 to 6 includes a plurality of sets of the insulating film, the resistance element, and the first to eighth contact members,
the sets separate from each other in the second direction in plan view,
the gate pad includes a gate pad wiring, and the gate pad wiring overlaps the first and second contact members in each of the plurality of the sets in plan view,
the gate wiring overlaps the third and fourth contact members in each of the plurality of the sets in plan view, and
the first conductive member overlaps the fifth to eighth contact members in each of the plurality of the sets in plan view.

### Statement 8

The semiconductor device according to any one of the statements 1 to 7 further includes:
a second conductive member formed on the interlayer insulating film; and
ninth to twelfth contact members penetrating the interlayer insulating film and reaching the resistance element,
the first connecting part includes:
eighth and ninth extended parts extending in the first direction, separating from each other in the second direction, and being arranged between the first and second extended parts in plan view;
a tenth extended part extending in the second direction and electrically connecting one end of the first extended part and one end of the eighth extended part;
an eleventh extended part extending in the second direction and electrically connecting one end of the second extended part and one end of the ninth extended part; and
a twelfth extended part extending in the second direction and electrically connecting the other end of the eighth extended part and the other end of the ninth extended part,
the ninth contact member electrically connects the second conductive member and the first extended part, the tenth contact member electrically connects the second conductive member and the eighth extended part, the eleventh contact member electrically connects the second conductive member and the ninth extended part, and the twelfth contact member electrically connects the second conductive member and the second extended part.

### Statement 9

In the semiconductor device according to any one of the statements 1 to 8,
the gate pad includes a gate pad wiring, the gate pad wiring has a width of at least a first predetermined length in the first direction in plan view, and the gate wiring has a width of at least a second predetermined length in the first direction in plan view.

### Statement 10

The semiconductor device according to any one of the statements 1 to 9 further includes:
an emitter electrode formed on the interlayer insulating film; and
a well contact member penetrating the interlayer insulating film and reaching the well region, and
the well contact member electrically connects the emitter electrode and the well region.

### Statement 11

A method of manufacturing a semiconductor device including steps of:
(a) preparing a semiconductor substrate having a first main surface;
(b) forming a well region on the first main surface of the semiconductor substrate;
(c) forming a trench in the well region, the trench forming a closed path in plan view;
(d) forming an insulating film inside the trench;
(e) forming a resistance element inside the trench through the insulating film;
(f) forming an interlayer insulating film on the first main surface;
(g) forming first to eighth contact members penetrating film and reaching the resistance the interlayer insulating element; and
(h) forming a gate pad, a gate wiring, and a first conductive member on the interlayer insulating film,
in the step (e),
the resistance element includes:
first and second extended parts extending in the first direction in plan view and separating from each other in a second direction crossing the first direction in plan view;
a first connecting part electrically connecting one end of the first extended part and one end of the second extended part; and
a second connecting part electrically connecting the other end of the first extended part and the other end of the second extended part,
in the steps (g) and (h),
the first and second contact members each electrically connects the gate pad and the resistance element,
the third and fourth contact members each electrically connects the gate wiring and the resistance element, and
the first to eighth contact members, the gate pad, the gate wiring, and the first conductive member are formed so that the fifth to eighth contact members each electrically connects the first conductive member and the resistance element.

### Statement 12

In the method of manufacturing the semiconductor device according to the statement 11,
in the step (e), the resistance element is formed so that the second connecting part includes:
third and fourth extended parts extending in the first direction, separating from each other in the second direction, and being arranged between the first and second extended parts in plan view;
a fifth extended part extending in the second direction and electrically connecting one end of the third extended part and one end of the fourth extended part;
a sixth extended part extending in the second direction and electrically connecting the other end of the first extended part and the other end of the third extended part; and
a seventh extended part extending in the second direction and electrically connecting the other end of the second extended part and the other end of the fourth extended part,
and, in the steps (g) and (h), the fifth to eighth contact members and the first conductive member are formed so that the fifth contact member electrically connects the first conductive member and the first extended part, so that the sixth contact member electrically connects the first conductive member and the third extended part, so that the seventh contact member electrically connects the first conductive member and the fourth extended part, and so that the eighth contact member electrically connects the first conductive member and the second extended part.

### Statement 13

In the method of manufacturing the semiconductor device according to the statement 11 or 12,
in the steps (g) and (h), the third and fourth contact members and the gate wiring are formed so that the third contact member electrically connects the gate wiring and the third extended part and so that the fourth contact member electrically connects the gate wiring and the fourth extended part.

### Statement 14

In the method of manufacturing the semiconductor device according to any one of the statements 11 to 13,
in the step (e), the resistance element is formed so that each width of the first to fourth extended parts in the second direction in plan view is larger than each width of the fifth to seventh extended parts in the first direction in plan view.

### Statement 15

In the method of manufacturing the semiconductor device according to any one of the statements 11 to 14,
in the step (g), the fifth to eighth contact members separate by at least a predetermined distance from the sixth and seventh extended parts in the first direction.

### Statement 16

In the method of manufacturing the semiconductor device according to any one of the statements 11 to 15,
in the step (g), the first to eighth contact members are formed so as to have a length within a predetermined range in the first direction.

### Statement 17

In the method of manufacturing the semiconductor device according to any one of the statements 11 to 16,
in the steps (c) to (e), a plurality of the trenches, a plurality of the insulating films, and a plurality of the resistance elements are formed,
in the step (g), the semiconductor device is configured to include a plurality of sets of the insulating g film, the resistance element, and the first to eighth contact members by formation of a plurality of the first to eighth contact members,
the sets separate from each other in the second direction in plan view,
in the step (h), the gate pad is formed so that the gate pad includes a gate pad wiring and so that the gate pad wiring overlaps the first and second contact members in each of the plurality of the sets in plan view,
in the step (h), the gate wiring is formed so as to overlap the third and fourth contact members in each of the plurality of the sets in plan view, and
in the step (h), the first conductive member is formed so as to overlap the fifth to eighth contact members in each of the plurality of the sets in plan view.

### Statement 18

In the method of manufacturing the semiconductor device according to any one of the statements 11 to 17,
in the step (g), the ninth to twelfth contact members penetrating the interlayer insulating film and reaching the resistance element are further formed,
in the step (h), a second conductive member is further formed on the interlayer insulating film,
in the step (e), the resistance element is formed so that the first connecting part includes:
eighth and ninth extended parts extending in the first direction, separating from each other in the second direction, and being arranged between the first and second extended parts in plan view;
a tenth extended part extending in the second direction and electrically connecting one end of the first extended part to one end of the eighth extended part;
an eleventh extended part extending in the second direction and electrically connecting one end of the second extended part and one end of the ninth extended part; and
a twelfth extended part extending in the second direction and electrically connecting the other end of the eighth extended part and the other end of the ninth extended part, and
in the steps (g) and (h), the ninth to twelfth contact members and the second conductive member are formed so that the ninth contact member electrically connects the second conductive member and the first extended part, so that the tenth contact member electrically connects the second conductive member and the eighth extended part, so that the eleventh contact member electrically connects the second conductive member and the ninth extended part, and so that the twelfth contact member electrically connects the second conductive member and the second extended part.

### Statement 19

In the method of manufacturing the semiconductor device according to any one of the statements 11 to 18,
in the step (h), the gate pad is formed so that the gate pad includes a gate pad wiring and so that the gate pad wiring has a width of at least a first predetermined length in the first direction in plan view, and the gate wiring is formed so that the gate wiring has a width of at least a second predetermined length in the first direction in plan view.

### Statement 20

In the method of manufacturing the semiconductor device according to any one of the statements 11 to 19,
in the step (g), a well contact member penetrating the interlayer insulating film and reaching the well region is further formed,
in the step (h), an emitter electrode is further formed on the interlayer insulating film, and
the well contact member electrically connects the emitter electrode and the well region.

What is claimed is:

1. A semiconductor device comprising:
a semiconductor substrate having a first main surface and a well region formed on the first main surface;
an interlayer insulating film formed on the first main surface;
a gate pad, a gate wiring, and a first conductive member formed on the interlayer insulating film;
a resistance element formed through an insulating film inside a trench that forms a closed path in plan view, the trench being formed in the well region; and
first to eighth contact members penetrating the interlayer insulating film and reaching the resistance element,
wherein the resistance element includes:
first and second extended parts extending in a first direction in plan view and separating from each other in a second direction crossing the first direction in plan view;
a first connecting part electrically connecting one end of the first extended part and one end of the second extended part; and
a second connecting part electrically connecting the other end of the first extended part and the other end of the second extended part,
wherein the first and second contact members each electrically connects the gate pad and the resistance element,
wherein the third and fourth contact members each electrically connects the gate wiring and the resistance element, and
wherein the fifth to the eighth contact member each electrically connects the first conductive member and the resistance element.

2. The semiconductor device according to claim 1,
wherein the second connecting part includes:
third and fourth extended parts extending in the first direction, separating from each other in the second direction, and being arranged between the first second extended parts in plan view;
a fifth extended part extending in the second direction and electrically connecting one end of the third extended part and one end of the fourth extended part;
a sixth extended part extending in the second direction and electrically connecting the other end of the first extended part and the other end of the third extended part; and
a seventh extended part extending in the second direction and electrically connecting the other end of the second extended part and the other end of the fourth extended part,
wherein the fifth contact member electrically connects the first conductive member and the first extended part,
wherein the sixth contact member electrically connects the first conductive member and the third extended part,
wherein the seventh contact member electrically connects the first conductive member and the fourth extended part, and
wherein the eighth contact member electrically connects the first conductive member and the second extended part.

3. The semiconductor device according to claim 2,
wherein the third contact member electrically connects the gate wiring and the third extended part, and the fourth contact member electrically connects the gate wiring and the fourth extended part.

4. The semiconductor device according to claim 2,
wherein each width of the first to fourth extended parts in the second direction in plan view is larger than each width of the fifth to seventh extended parts in the first direction in plan view.

5. The semiconductor device according to claim 2,
wherein the fifth to eighth contact members separate by at least a predetermined distance from the sixth and seventh extended parts in the first direction.

6. The semiconductor device according to claim 1,
wherein the first to eighth contact members each has a length within a predetermined range in the first direction.

7. The semiconductor device according to claim 1 further comprising
a plurality of sets of the insulating film, the resistance element, and the first to eighth contact members,
wherein the sets separate from each other in the second direction in plan view,
wherein the gate pad includes a gate pad wiring, and the gate pad wiring overlaps the first and second contact members in each of the plurality of the sets in plan view,
wherein the gate wiring overlaps the third and fourth contact members in each of the plurality of the sets in plan view, and
wherein the first conductive member overlaps the fifth to eighth contact members in each of the plurality of the sets in plan view.

8. The semiconductor device according to claim 1 further comprising:
a second conductive member formed on the interlayer insulating film; and
ninth to twelfth contact members penetrating the interlayer insulating film and reaching the resistance element,
wherein the first connecting part includes:
eighth and ninth extended parts extending in the first direction, from each other in the second direction, and being arranged between the first and second extended parts in plan view;
a tenth extended part extending in the second direction and electrically connecting one end of the first extended part and one end of the eighth extended part;
an eleventh extended part extending in the second direction and electrically connecting one end of the second extended part and one end of the ninth extended part; and
a twelfth extended part extending in the second direction and electrically connecting the other end of the eighth extended part and the other end of the ninth extended part,
wherein the ninth contact member electrically connects the second conductive member and the first extended part, the tenth contact member electrically connects the second conductive member and the eighth extended part, the eleventh contact member electrically connects the second conductive member and the ninth extended part, and the twelfth contact member electrically connects the second conductive member and the second extended part.

9. The semiconductor device according to claim 1,
wherein the gate pad includes a gate pad wiring, the gate pad wiring has a width of at least a first predetermined length in the first direction in plan view, and the gate wiring has a width of at least a second predetermined length in the first direction in plan view.

10. The semiconductor device according to claim 1 further comprising:
an emitter electrode formed on the interlayer insulating film; and
a well contact member penetrating the interlayer insulating film and reaching the well region, and
wherein the well contact member electrically connects the emitter electrode and the well region.

11. A method of manufacturing a semiconductor device comprising steps of:
(a) preparing a semiconductor substrate having a first main surface;
(b) forming a well region on the first main surface of the semiconductor substrate;
(c) forming a trench in the well region, the trench forming a closed path in plan view;
(d) forming an insulating film inside the trench;
(e) forming a resistance element inside the trench through the insulating film;
(f) forming an interlayer insulating film on the first main surface;
(g) forming first to eighth contact members penetrating the interlayer insulating film and reaching the resistance element; and
(h) forming a gate pad, a gate wiring, and a first conductive member on the interlayer insulating film,
wherein, in the step (e),
the resistance element includes:
first and second extended parts extending in the first direction in plan view and separating from each other in a second direction crossing the first direction in plan view;
a first connecting part electrically connecting one end of the first extended part and one end of the second extended part; and
a second connecting part electrically connecting the other end of the first extended part and the other end of the second extended part,
wherein, in the steps (g) and (h),
the first and second contact members each electrically connects the gate pad and the resistance element,
the third and fourth contact members each electrically connects the gate wiring and the resistance element, and
the first to eighth contact members, the gate pad, the gate wiring, and the first conductive member are formed so that the fifth to eighth contact members each electrically connects the first conductive member and the resistance element.

12. The method of manufacturing the semiconductor device according to claim 11,
wherein, in the step (e), the resistance element is formed so that the second connecting part includes:
third and fourth extended parts extending in the first direction, separating from each other in the second direction, and being arranged between the first and second extended parts in plan view;
a fifth extended part extending in the second direction and electrically connecting one end of the third extended part and one end of the fourth extended part;
a sixth extended part extending in the second direction and electrically connecting the other end of the first extended part and the other end of the third extended part; and
a seventh extended part extending in the second direction and electrically connecting the other end of the second extended part and the other end of the fourth extended part, and,
wherein, in the steps (g) and (h), the fifth to eighth contact members and the first conductive member are formed so that the fifth contact member electrically connects the first conductive member and the first extended part, so that the sixth contact member electrically connects the first conductive member and the third extended part, so that the seventh contact member electrically connects the first conductive member and the fourth extended part, and so that the eighth contact member electrically connects the first conductive member and the second extended part.

13. The method of manufacturing the semiconductor device according to claim 12,
wherein, in the steps (g) and (h), the third and fourth contact members and the gate wiring are formed so that the third contact member electrically connects the gate wiring and the third extended part and so that the fourth contact member electrically connects the gate wiring and the fourth extended part.

14. The method of manufacturing the semiconductor device according to claim 12,
wherein, in the step (e), the resistance element is formed so that each width of the first to fourth extended parts in the second direction in plan view is larger than each width of the fifth to seventh extended parts in the first direction in plan view.

15. The method of manufacturing the semiconductor device according to claim 12,
wherein, in the step (g), the fifth to eighth contact members separate by at least a predetermined distance from the sixth and seventh extended parts in the first direction.

16. The method of manufacturing the semiconductor device according to claim 11,
wherein, in the step (g), the first to eighth contact members are formed so as to have a length within a predetermined range in the first direction.

17. The method of manufacturing the semiconductor device according to claim 11,
wherein, in the steps (c) to (e), a plurality of the trenches, a plurality of the insulating films, and a plurality of the resistance elements are formed,
wherein, in the step (g), the semiconductor device is configured to include a plurality of sets of the insulating film, the resistance element, and the first to eighth contact members by formation of a plurality of the first to eighth contact members,
wherein the sets separate from each other in the second direction in plan view,
wherein, in the step (h), the gate pad is formed so that the gate pad includes a gate pad wiring and so that the gate pad wiring overlaps the first and second contact members in each of the plurality of the sets in plan view,
wherein, in the step (h), the gate wiring is formed so as to overlap the third and fourth contact members in each of the plurality of the sets in plan view, and
wherein, in the step (h), the first conductive member is formed so as to overlap the fifth to eighth contact members in each of the plurality of the sets in plan view.

18. The method of manufacturing the semiconductor device according to claim 11,
wherein, in the step (g), the ninth to twelfth contact members penetrating the interlayer insulating film and reaching the resistance element are further formed,
wherein, in the step (h), a second conductive member is further formed on the interlayer insulating film,
wherein, in the step (e), the resistance element is formed so that the first connecting part includes:
eighth and ninth extended parts extending in the first direction, separating from each other in the second direction, and being arranged between the first and second extended parts in plan view;
a tenth extended part extending in the second direction and electrically connecting one end of the first extended part to one end of the eighth extended part;
an eleventh extended part extending in the second direction and electrically connecting one end of the second extended part and one end of the ninth extended part; and
a twelfth extended part extending in the second direction and electrically connecting the other end of the eighth extended part and the other end of the ninth extended part, and
wherein, in the steps (g) and (h), the ninth to twelfth contact members and the second conductive member are formed so that the ninth contact member electrically connects the second conductive member and the first extended part, so that the tenth contact member electrically connects the second conductive member and the eighth extended part, so that the eleventh contact member electrically connects the second conductive member and the ninth extended part, and so that the twelfth contact member electrically connects the second conductive member and the second extended part.

19. The method of manufacturing the semiconductor device according to claim 11,
wherein, in the step (h), the gate pad is formed so that the gate pad includes a gate pad wiring and so that the gate pad wiring has a width of at least a first predetermined length in the first direction in plan view, and the gate wiring is formed so that the gate wiring has a width of at least a second predetermined length in the first direction in plan view.

20. The method of manufacturing the semiconductor device according to claim 11,
wherein, in the step (g), a well contact member penetrating the interlayer insulating film and reaching the well region is further formed,
wherein, in the step (h), an emitter electrode is further formed on the interlayer insulating film, and
wherein the well contact member electrically connects the emitter electrode and the well region.
